(19) United States
(12) Patent Application Publication
(10) Pub. No.: US 2017/0141537 A1
(43) Pub. Date: May 18, 2017

(54) LASER DEVICE, OPTICAL AMPLIFIER, OPTICAL TRANSMISSION DEVICE, AND DETERMINATION METHOD

(71) Applicant: FUJITSU LIMITED, Kawasaki-shi (JP)

(72) Inventor: Miki ONAKA, Kawasaki (JP)

(73) Assignee: FUJITSU LIMITED, Kawasaki-shi (JP)

(21) Appl. No.: 15/286,798

(22) Filed: Oct. 6, 2016

(30) Foreign Application Priority Data
Nov. 18, 2015 (JP) 2015-225298

(51) Int. Cl. H01S 5/068; H01S 5/042; H01S 5/42; H01S 5/183; H01S 5/06; H01S 5/0683

(52) U.S. Cl. CPC H01S 5/06825; H01S 5/0617; H01S 5/0683; H01S 5/423; H01S 5/183; H01S 5/0425

(57) ABSTRACT

A laser device includes: a semiconductor laser; a detection circuit which detects optical power in each position of a spot of emission light which is emitted from the semiconductor laser; and a determination circuit which calculates a power distribution of the spot of the emission light and total power of the spot based on the optical power detected by the detection circuit to determine a sudden death failure sign of the semiconductor laser based on the calculated power distribution and the total power.

### CROSS-REFERENCE TO RELATED APPLICATION

This application is based upon and claims the benefit of priority of the prior Japanese Patent Application No. 2015-225298, filed on Nov. 18, 2015, the entire contents of which are incorporated herein by reference.

### FIELD

The embodiment discussed herein is related to a laser device, an optical amplifier, an optical transmission device, and a determination method.

### BACKGROUND

In recent years, a laser driving device which compares an output characteristic detected by receiving a part of laser beam emitted from a semiconductor laser and a predetermined reference output characteristic and changes a driving current to be supplied to the semiconductor laser according to a comparison result is known.

In addition, a failure detection method for detecting a failure in a semiconductor laser such that a current having a value less than a predetermined current value is supplied to the semiconductor laser and a non-oscillating and light emitting image of the semiconductor laser, of which a laser oscillation does not occur, is obtained is known.

However, in the above-described related art, there is a problem in that a sudden death failure, in which a semiconductor optical device such as a semiconductor laser or a semiconductor optical amplifier is rapidly degraded and stops operating, is difficult to be predicted with high accuracy.

The followings are reference documents.

[Document 1] Japanese Laid-open Patent Publication No. 2006-303365 and

[Document 2] Japanese Laid-open Patent Publication No. 2013-251324.

### SUMMARY

According to an aspect of the invention, a laser device includes: a semiconductor laser; a detection circuit which detects optical power in each position of a spot of emission light which is emitted from the semiconductor laser; and a determination circuit which calculates a power distribution of the spot of the emission light and total power of the spot based on the optical power detected by the detection circuit to determine a sudden death failure sign of the semiconductor laser based on the calculated power distribution and the total power.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1 is a diagram illustrating an example of a laser device according to an embodiment;

FIG. 2 is a diagram illustrating another example of the laser device according to the embodiment;

FIG. 3 is a diagram illustrating an example of an optical amplifier using an LD according to the embodiment;

FIG. 4 is a diagram illustrating another example of the optical amplifier using an LD according to the embodiment;

FIG. 5 is a diagram illustrating an example of an optical amplifier using a SOA according to the embodiment;

FIG. 6 is a diagram illustrating another example of an optical amplifier using a semiconductor optical amplifier according to the present embodiment;

FIG. 7 is a front cross-section view illustrating an example of a crystal defect generated on the LD according to the embodiment;

FIG. 8 is a diagram illustrating an example of an output power distribution of the LD (a normal article) according to the embodiment;

FIG. 9 is a diagram illustrating an example of the output power distribution of the LD (a crystal defect generated article) according to the embodiment;

FIG. 10 is a diagram illustrating an example of two-dimensionally arranged photo detectors included in a detection unit according to the embodiment;

FIG. 11 is a diagram illustrating an example of a radiation of the LD (the normal article) to the two-dimensionally arranged photo detectors according to the embodiment;

FIG. 12 is a diagram illustrating an example of a detection result of a two-dimensional output power distribution of the LD (the normal article) according to the embodiment;

FIG. 13 is a diagram illustrating an example of a radiation of the LD (the crystal defect generated article) to the two-dimensionally arranged photo detectors according to the embodiment;

FIG. 14 is a diagram illustrating an example of a detection result of a two-dimensional output power distribution of the LD (the crystal defect generated article) according to the embodiment;

FIG. 15 is a diagram illustrating an example of the output power distribution of the LD (the normal article) in an X-axis direction according to the embodiment;

FIG. 16 is a diagram illustrating an example of the output power distribution of the LD (the normal article) in a Y-axis direction according to the embodiment;

FIG. 17 is a diagram illustrating an example of information to be stored in a determination unit according to the embodiment;

FIG. 18 is a diagram illustrating an example of an optical transmission device on which the LDs are mounted with a high density according to the embodiment;

FIG. 19 is a diagram illustrating another example of the two-dimensionally arranged photo detectors included in the detection unit according to the embodiment;

FIG. 20 is a diagram illustrating an example of a radiation of a plurality of LDs (normal articles) to the two-dimensionally arranged photo detectors according to the embodiment;

FIG. 21 is a diagram illustrating another example of the information to be stored in the determination unit according to the embodiment;

FIG. 22 is a diagram (Example 1) illustrating an example of an LD switching based on a detection result of a determination device according to the embodiment;

FIG. 23 is a diagram (Example 2) illustrating an example of the LD switching based on the detection result of the determination device according to the embodiment;

FIG. 24 is a diagram (Example 1) illustrating an example of a change in a spot due to the LD switching according to the embodiment;

FIG. 25 is a diagram (Example 2) illustrating an example of the change in the spot due to the LD switching according to the embodiment;

FIG. 26 is a flow chart illustrating an example of a process by the optical transmission device according to the embodiment;

FIG. 27 is a flow chart illustrating an example of a determination process of a sudden death failure sign by the optical transmission device according to the embodiment;

FIG. 28 is a flow chart illustrating an example of a notifying and switching process by the optical transmission device according to the embodiment;

FIG. 29 is a diagram illustrating an example of an optical transmission system according to the embodiment;

FIG. 30 is a diagram illustrating an example of a calculation of the output power distribution of each LD according to the embodiment;

FIG. 31 is a diagram illustrating an example of a correction of a monitoring region of the LD according to the embodiment;

FIG. 32 is a front cross-section view illustrating an example of an LD array according to the embodiment;

FIG. 33 is a diagram illustrating an example of a spot of a back light of a VCSEL array (at a normal time) according to the embodiment;

FIG. 34 a diagram illustrating an example of the spot of the back light of the VCSEL array (at a time when degradation occurs) according to the embodiment;

FIG. 35 is a front cross-section diagram illustrating another example of the LD array according to the embodiment;

FIG. 36 is a front cross-section diagram illustrating still another example of the LD array according to the embodiment;

FIG. 37 is a diagram illustrating an example of a tolerance with respect to a variation of a spot radiation according to the embodiment; and

FIG. 38 is a diagram illustrating an example of a characteristic change in the LD according to the embodiment.

### DESCRIPTION OF EMBODIMENT

Hereinafter, a laser device, an optical amplifier, an optical transmission device, and a determination method according to an embodiment will be described in detail with reference to the drawings.

### Embodiment

### Laser Device According to Embodiment

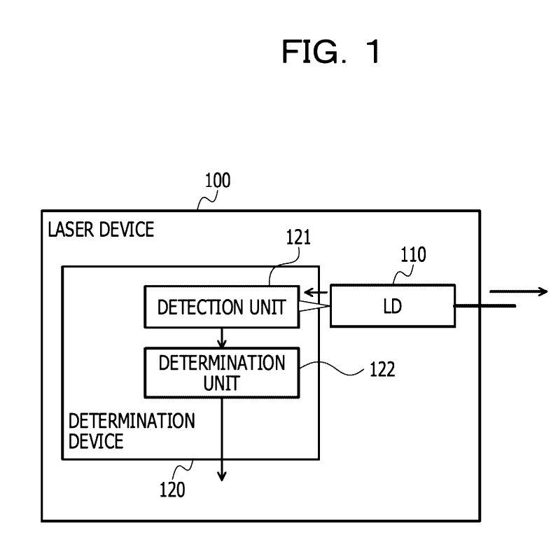

FIG. 1 is a diagram illustrating an example of a laser device according to an embodiment. As illustrated in FIG. 1, a laser device 100 according to the embodiment includes a laser diode (LD) 110 and a determination device 120.

The LD 110 is a semiconductor laser which oscillates light in accordance with an input driving current and emits the oscillated light. In the LD 110, an LD including aluminum and gallium arsenide in an active layer can be used as an example. However, it is not limited thereto, and various types of LDs can be used.

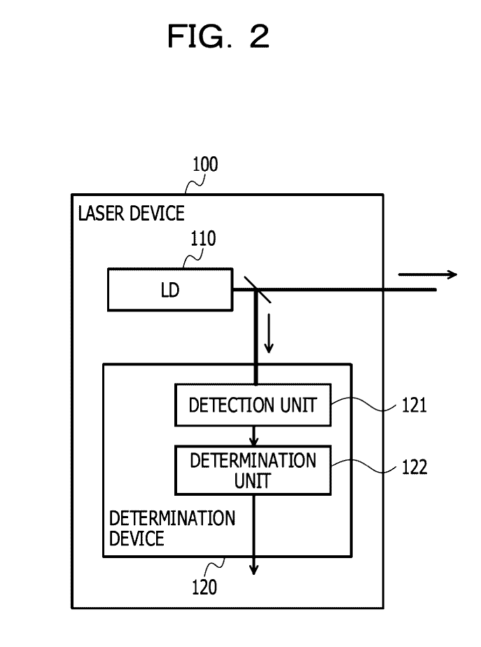

The determination device 120 determines a sudden death failure sign of the LD 110. Emission light (laser beam) of the LD 110 is incident in the determination device 120. In the example illustrated in FIG. 1, there is a configuration in which a back emission light (back light) emitted from the LD 110 is incident to the determination device 120. According to this, it is possible to monitor output power of the LD 110 even when a front emission light (front light) of the LD 110 is not dispersed. In addition, since the back emission light emitted from the LD 110 can be spatial coupled such that the back emission light is incident to the determination device 120 without through a transmission path such as an optical fiber. However, a configuration in which the front emission light (front light) emitted from the LD 110 is dispersed and incident to the determination device 120 may be used (for example, refer to FIG. 2).

The determination device 120 includes, for example, a detection unit 121 and a determination unit 122. The detection unit 121 detects optical power in each position of a spot of emission light of the LD 110. The detection unit 121 outputs a detection result to the determination unit 122. The spot of the emission light of the LD 110 is a radiation region of a laser beam from the LD 110 with respect to a surface orthogonal to the laser beam emitted from the LD 110 in an emitting direction.

As an example, the detection unit 121 can be obtained by a plurality of photo detectors which are two-dimensionally arranged on a surface orthogonal to the laser beam emitted from the LD 110 in an emitting direction. In this case, a pitch of the plurality of photo detectors which are two-dimensionally arranged is smaller than a width of the spot of the emission light of the LD 110. According to this, by the plurality of photo detectors, power in each position of the spot of the emission light of the LD 110 can be detected. However, the detection unit 121 is not limited to the photo detectors in a two-dimensional arrangement. For example, the detection unit 121 can be obtained by moveable photo detectors in a one-dimensional arrangement or a single photo detector. There configurations will be described below.

The determination unit 122 calculates a power distribution of the spot of the emission light of the LD 110 and total power of the spot of the emission light of the LD 110 based on the detection result output from the detection unit 121. The power distribution of the spot is a distribution of power in each position of the spot and has, for example, a far field pattern (FFP). For example, in a case where the detection unit 121 is configured of a plurality of photo detectors in the two-dimensional arrangement, the determination unit 122 can obtain a two-dimensional distribution of the spot by mapping each of light receiving currents which are obtained by the plurality of photo detectors.

The total power of the spot is a total value of power in each position of the spot. For example, in a case where the detection unit 121 is configured of the plurality of photo detectors in the two-dimensional arrangement, the determination unit 122 can obtain the total power of the spot by adding each of the light receiving currents obtained by the plurality of photo detectors.

The determination unit 122 determines a presence and absence of the sudden death failure sign of the LD 110 based on the calculated power distribution and the total power and outputs the determination results. For example, the determination unit 122 calculates a feature value of a shape of the power distribution of the spot of the emission light of the LD 110 and determines the presence and absence of the sudden death failure sign of the LD 110 based on the calculated feature value and the total power.

For example, the determination unit 122 outputs the determination result to a maintenance person of a laser device 100. The determination unit 122 may output the determination result to a control circuit of the LD 110, for example. The determination of the sudden death failure sign by the determination unit 122 will be described below.

In addition, the determination device 120 may be provided in a device different from the LD 110. For example, the determination device 120 may be provided in a relay device for relaying signal light transmitted by the LD 110 or a light receiving device for receiving the signal light transmitted by the LD 110.

FIG. 2 is a diagram illustrating another example of the laser device according to the embodiment. In FIG. 2, same reference numerals are used for denoting the same configuration as that of FIG. 1 and descriptions thereof will not be described. As illustrated in FIG. 2, in the laser device 100, a configuration that the front emission light (front light) emitted from the LD 110 is dispersed and incident to the determination device 120 may be used.

Optical Amplifier Using LD According to Embodiment

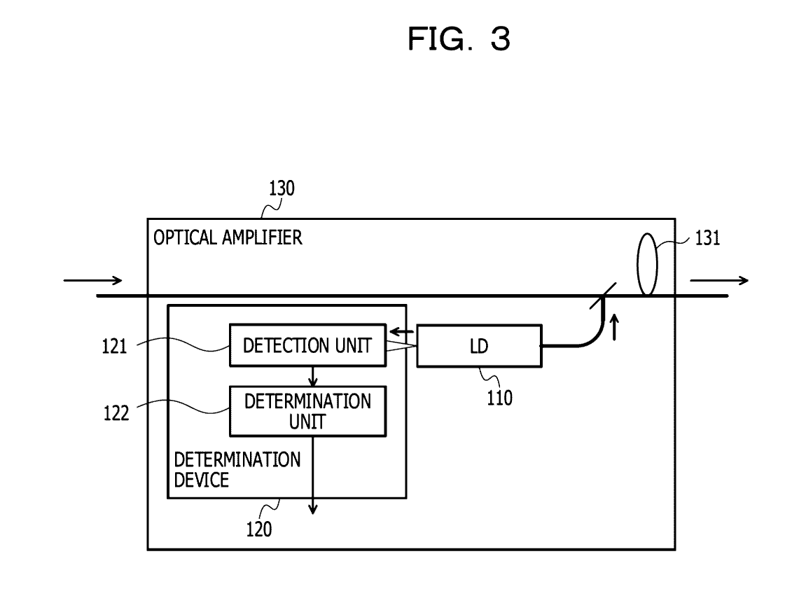

FIG. 3 is a diagram illustrating an example of an optical amplifier using an LD according to the embodiment. In FIG. 3, same reference numerals are used for denoting the same portion as the portion of FIG. 1 and descriptions thereof will not be described. As illustrated in FIG. 3, an optical amplifier 130 according to the embodiment includes the LD 110, the determination device 120, and an optical amplifier medium 131.

The optical amplifier medium 131 is an optical amplifier medium which allows incident light to the optical amplifier 130 and the emission light of the LD 110 to be passed to the optical amplifier 130 to amplify and emit the incident light to the optical amplifier 130. The optical amplifier medium 131 is, for example, an erbium doped fiber (EDF).

FIG. 3 illustrates a co-propagating configuration in which the incident light to the optical amplifier 130 is multiplexed with the emission light of the LD 110 and the multiplexed light is incident from a preceding stage of the optical amplifier medium 131. With respect to this, for example, a counter-propagating configuration that the incident light to the optical amplifier 130 is incident from the preceding stage of the optical amplifier medium 131 and the emission light of the LD 110 is incident from a subsequent stage of the optical amplifier medium 131 may be used. In addition, a bidirectional-propagating configuration which combines the co-propagating configuration and the counter-propagating configuration may be used.

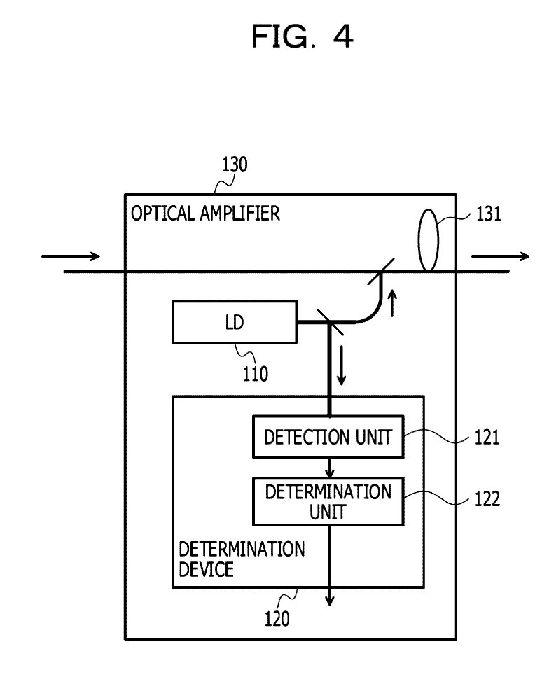

FIG. 4 is a diagram illustrating another example of the optical amplifier using an LD according to the embodiment. In FIG. 4, same reference numerals are used for denoting the same configuration as that of FIG. 3 and descriptions thereof will not be described. As illustrated in FIG. 4, in the optical amplifier 130, a configuration that the front emission light (front light) emitted from the LD 110 is dispersed and incident to the determination device 120.

Optical Amplifier Using SOA According to Embodiment

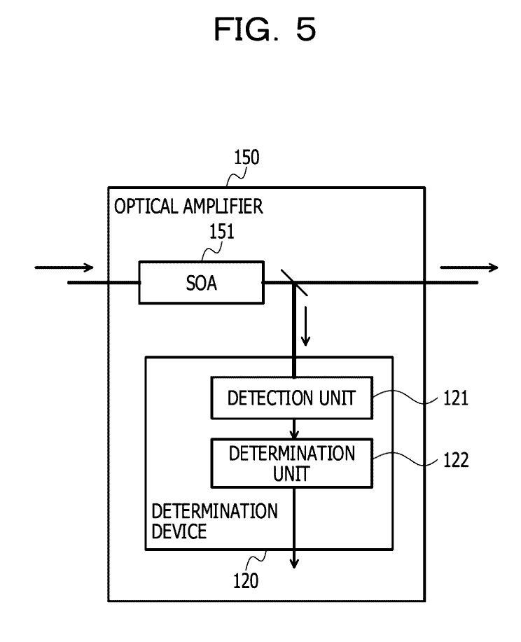

FIG. 5 is a diagram illustrating an example of an optical amplifier using a SOA according to the embodiment. In FIG. 5, same reference numerals are used for denoting the same portion as the portion of FIG. 1 and descriptions thereof will not be described. As illustrated in FIG. 5, an optical amplifier 150 according to the embodiment includes a semiconductor optical amplifier (SOA) 151 and the determination device 120.

The SOA 151 is a semiconductor optical amplifier which amplifies and emits the light incident according to a driving current to be input. In addition, an amplified spontaneous emission (ASE) light is emitted from the SOA 151.

Since the SOA uses a principle of a laser-induced ejection in the same manner as the LD, there is a risk of a sudden death failure in the same manner as the LD. In addition, when aluminum is included in an active layer of the LD, efficiency (driving current versus light output power) at a high temperature can be improved in the same manner as the LD. However, the aluminum is easily combined with oxygen, and it leads to rapidly increase crystal defect. Accordingly, the risk of the sudden death failure increases.

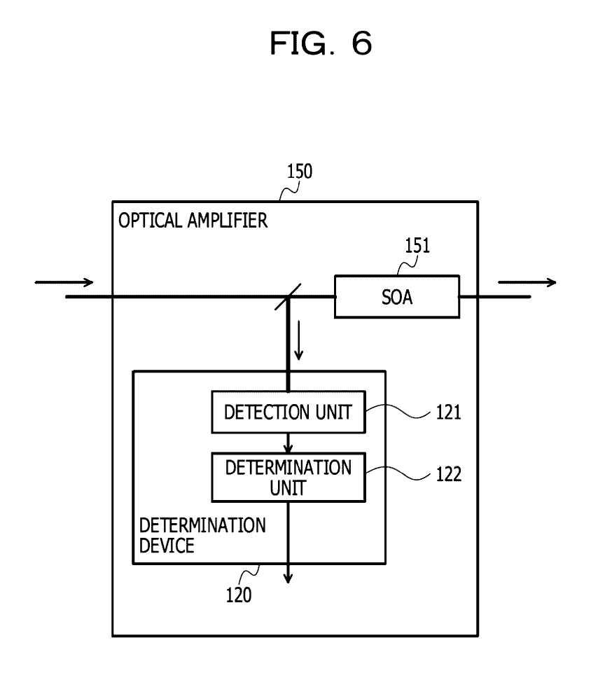

The determination device 120 determines a sudden death failure sign of the SOA 151. In the determination device 120, the ASE light is incident from the SOA 151. In FIG. 5, a configuration that the front emission light emitted from the SOA 151 is incident from the determination device 120 is illustrated. In a case where an isolator is not provided in an input unit of the SOA 151, for example, a configuration that the front emission light (black light) emitted from the SOA 151 is incident to the determination device 120 may be used (for example, refer to FIG. 6).

The detection unit 121 detects power of the ASE light form the SOA 151. The determination unit 122 determines a presence and absence of the sudden death failure sign of the SOA 151 based on the detection result output from the detection unit 121.

FIG. 6 is a diagram illustrating another example of the optical amplifier using a semiconductor optical amplifier according to the present embodiment. In FIG. 6, same reference numerals are used for denoting the same portion as the portion of FIG. 5 and descriptions thereof will not be described. As illustrated in FIG. 6, in the optical amplifier 150, in a case where the isolator is not provided in the input unit of the SOA 151, for example, a configuration that the front emission light (black light) emitted from the SOA 151 is incident to the determination device 120 may be used. According to this, it is possible to monitor the output power of the LD 110 even when the front emission light of the SOA 151 is not dispersed.

In this manner, according to the determination device 120 according to the embodiment, regarding the LD 110 or the SOA 151, by using the power distribution of the spot early appearing as a precursor of a sudden death failure, the sudden death failure sign can be determined early. Furthermore, the determination device 120 can accurately determine the sudden death failure sign by using a combination of the total power and the power distribution of the spot. According to this, the sudden death failure in a semiconductor optical device such as the LD 110 or the SOA 151 can be predicted early with high accuracy. If the sudden death failure in the semiconductor optical device can be predicted with high accuracy, for example, a switching of equipment can be performed before the sudden death failure.

In addition, the emission light emitted from the LD 110 or the SOA 151 is received without through a long optical fiber or the like. Therefore, it is possible to avoid that when the power distribution of the spot of the emission light is changed by the emission light is passed through the long optical fiber or the like, it is difficult to determine the sudden death failure sign.

Regarding Determination of Sudden Death Failure Sign Based on Power Distribution and Total Power

Here, the determination of the sudden death failure sign of the LD 110 will be described. The same description is applied to the determination of the sudden death failure sign of the SOA 151. For example, in a case where the calculated power distribution satisfies a predetermined first condition and the calculated total power satisfies a predetermined second condition, the determination unit 122 determines that there is the sudden death failure sign of the LD 110. On the other hand, in a case where the power distribution does not satisfy the first condition or the total power does not satisfy the second condition, the determination unit 122 determines that there is no sudden death failure sign in the LD 110. That is, only a case where each of the power distribution and the total power satisfies the predetermined condition, the determination unit 122 determines that there is the sudden death failure sign. According to this, the sudden death failure sign of the LD 110 can be accurately determined.

The first condition relating to the power distribution can be set such that a magnitude (absolute value) of a difference between a feature amount of a shape of the power distribution and a predetermined first reference value is equal to or greater than a predetermined first threshold value. That is, in a case where the shape of the power distribution is greatly deformed from the predetermined shape, the first condition is satisfied. The predetermined first reference value can be set as an initial value of the feature value of the shape of the power distribution, that is, a feature value of the shape of the power distribution in a state where there is no sudden death failure sign in the LD 110, as an example. However, the predetermined first reference value is not limited thereto, and may be a fixed value which is set by an examination or a simulation, for example.

The second condition relating to the total power can be set such that a magnitude (absolute value) of a difference between the total power and a predetermined second reference value is less than a predetermined second threshold value. That is, in a case where the total power is greatly varied from the predetermined value, the second condition is satisfied. The predetermined second reference value can be set as an initial value of the total power, that is, a total power in a state where there is no sudden death failure sign in the LD 110, as an example. However, the predetermined second reference value is not limited thereto, and may be a fixed value which is set by the examination or the simulation, for example.

In this manner, by using the total power is combined with the power distribution of the spot, for example, even when the power distribution of the spot is varied, it can be determined that there is no sudden death failure sign, in a case where a variation greatly occurs in the total power. According to this, for example, in a case where the variation of the power distribution occurs, regardless of the sudden death failure of the LD 110 by a disturbance due to a vibration in the laser device 100, it is possible to avoid an erroneous determination that there is the sudden death failure sign of the LD 110. Accordingly, the sudden death failure sign of the LD 110 can be accurately determined.

Power Distribution to be Calculated by Determination Unit

In a case where the detection unit 121 can detect the power of each two-dimensional state position of the spot, the power distribution of the spot to be calculated by the determination unit 122 can be set as a two-dimensional distribution (two-dimensional output power distribution) of the spot, for example. According to this, since the sudden death failure sign can be determined regardless of a deformation type (for example, a position where a second or later peak appears) of the shape of the two-dimensional power distribution of the spot appearing as the sudden death failure sign of the LD 110 or the SOA 151, it is possible to suppress a detection omission of the sudden death failure sign.

However, the power distribution of the spot to be calculated by the determination unit 122 may be a one-dimensional power distribution of the spot. In this case, the sudden death failure sign of the LD 110 or the SOA 151 can be determined by the deformation type (for example, a position where a second or later peak appears) of the shape of the two-dimensional power distribution of the spot appearing as the sudden death failure sign of the LD 110 or the SOA 151. In addition, in this case, since the detection unit 121 can detect the power of each one-dimensional position of the spot, the size of the detection unit 121 can be reduced. In addition, a process amount in the determination unit 122 can be reduced.

Each Position where Detection Unit Detects Power

The detection unit 121 may detect the power in each position of a region wider than the spot of the emission light and each potion which has a pitch narrower than a width of the spot of the emission light. According to this, the power in each position of the spot can be detected, and even when a positional relationship between a position of the spot of the emission light and the detection unit 121 is shifted, the spot of the emission light can be set so as to fit into a region where the detection unit 121 can detect the power.

These shifts occur due to a dimension accuracy of each component of the device, an assemble accuracy of each component of the device, a secular change of each component of the device during operating. However, even when such a shift occurs, the spot of the emission light can be set so as to fit into a region where the detection unit 121 can detect the power. According to this, it can liberalize a criterion of the dimension accuracy of each component of the device, the assemble accuracy of each component of the device, a durability of each component of the device to obtain reduction in a manufacturing cost of the device. In addition, the determination of the sudden death failure can be stably performed for a prolonged period.

Regarding Operation During Detection of Sudden Death Failure Sign

In addition, the laser device 100 or the optical amplifier 130 may include a plurality of LDs 110. Each of the plurality of LDs 110 may be formed as different files and may be formed by providing a plurality of electrodes and an active layer on one chip. In a case where the determination unit 122 determines that there is the sudden death failure sign, the laser device 100 or the optical amplifier 130 includes a control unit which is configured to switch a driving LD among the plurality of LDs 110.

According to this, in a case where the sudden death failure sign is detected in the LD used among the plurality of LDs 110, it is possible to avoid that the transmission of an optical signal is interrupted (system down) by switching the LD 110 used. However, the laser device 100 or the optical amplifier 130 is not limited to such as a lengthy configuration, and may be a configuration including one LD 110.

In addition, similarly, the optical amplifier 150 may include a plurality of SOAs 151. Each of the plurality of SOAs 151 may be formed as different files and may be formed by providing a plurality of electrodes and an active layer on one chip. In a case where the determination unit 122 determines that there is the sudden death failure sign, the optical amplifier 150 includes the control unit which is configured to switch a driving semiconductor optical amplifier among the plurality of SOAs 151.

According to this, in a case where the sudden death failure sign is detected in the semiconductor optical amplifier used among the plurality of SOAs 151, it is possible to avoid that the transmission of an optical signal is interrupted (system down) by switching the semiconductor optical amplifier used. However, the optical amplifier 150 is not limited to such as a lengthy configuration, and may be a configuration including one SOA 151.

Hereinafter, the configurations of the laser device 100 will be mainly described in detail. However, these configurations can be applicable and applied to the optical amplifier 130 or the optical amplifier 150.

Crystal Defect Generated on LD According to Embodiment

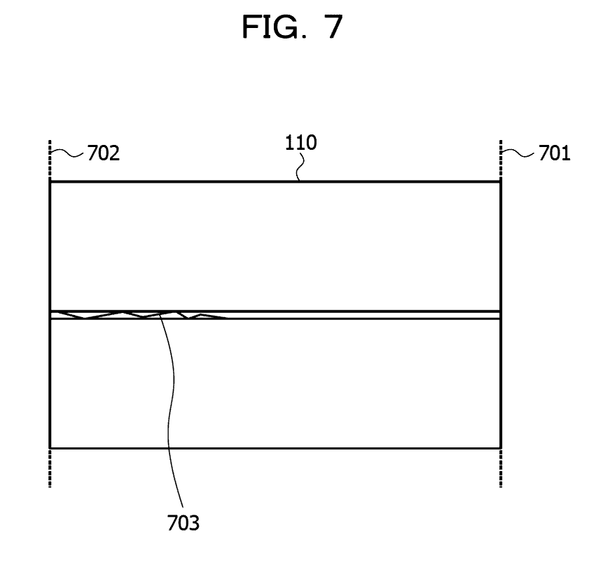

FIG. 7 is a front cross-section view illustrating an example of a crystal defect generated on the LD according to the embodiment. In FIG. 7, a front end surface 701 is an end surface of the front of the LD 110 and a rear end surface 702 is an end surface of the LD 110. In the LD 110, there is a case where the crystal defect such as a dark line defect (DLD) 703 occurs as illustrated in FIG. 7, for example. The sudden death failure of the LD 110 is occurred caused by, for example, such a DLD 703.

Output Power Distribution of LD According to Embodiment

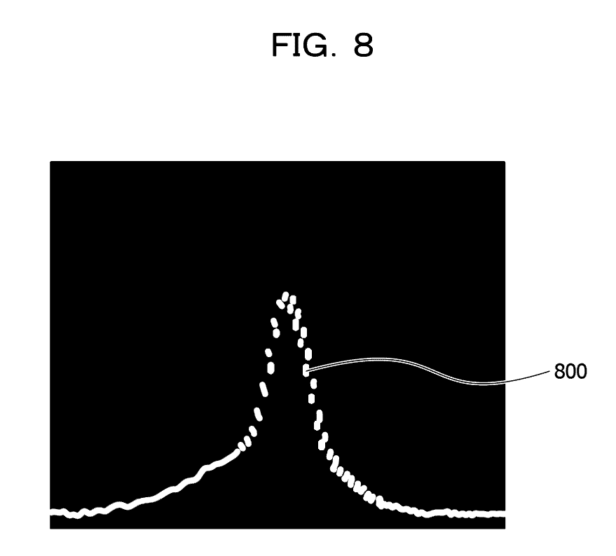

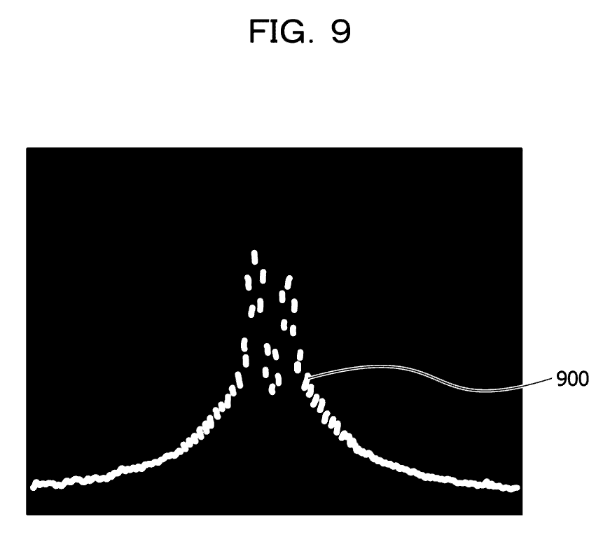

FIG. 8 is a diagram illustrating an example of an output power distribution of the LD (a normal article) according to the embodiment. FIG. 9 is a diagram illustrating an example of the output power distribution of the LD (a crystal defect generated article) according to the embodiment. In FIGS. 8 and 9, a horizontal direction indicates each position of the spot of the laser beam emitted from the LD 110 and a vertical direction indicates optical power.

An output power distribution 800 illustrate in FIG. 8 is, for example, the optical power in each position of the spot of the laser beam emitted from the LD 110 in which the crystal defect does not occur such as the DLD 703 illustrated in FIG. 7. The output power distribution 800 is a gauss distribution having one peak.

An output power distribution 900 illustrated in FIG. 9, for example, the optical power in each position of the spot of the laser beam emitted from the LD 110 in which the crystal defect does not occur such as the DLD 703 illustrated in FIG. 7. The output power distribution 900 becomes a distribution in which plurality of peaks are present as illustrated in FIG. 9 or a distribution which is collapsed (not illustrated) compared to the output power distribution 800 of FIG. 8.

Two-Dimensionally Arranged Photo Detectors Included in Detection Unit According to Embodiment

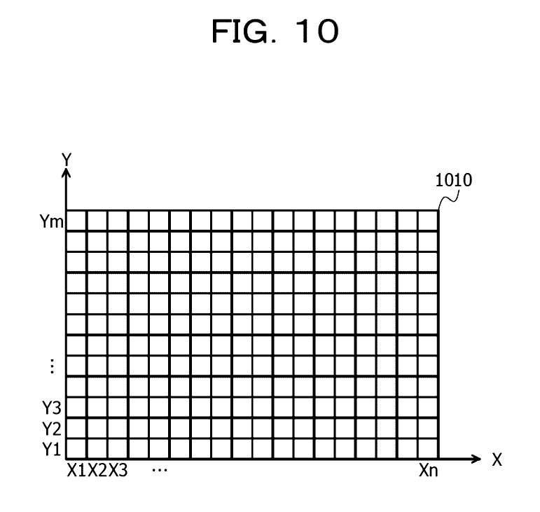

FIG. 10 is a diagram illustrating an example of two-dimensionally arranged photo detectors included in the detection unit according to the embodiment. Above-described detection unit 121 includes, for example, the two-dimensionally arranged photo detectors 1010 illustrated in FIG. 10. The two-dimensionally arranged photo detectors 1010 are a one-chip area sensor which is formed by arranging a plurality of photo detectors (PD) in two-dimensionally. The X-axis and the Y-axis illustrated in FIG. 10 define a light receiving surface of the two-dimensionally arranged photo detectors 1010, that is, a light receiving surface orthogonal to the laser beam in a radiation direction, as a XY plane.

X1, X2, X3, . . . , and Xn of the X-axis indicate a first row, a second row, a third row, . . . , a n-row in the two-dimensionally arranged photo detectors 1010. Y1, Y2, Y3, . . . , and Ym of the Y-axis indicate a first column, a second column, a third column, . . . , a m-column, in the two-dimensionally arranged photo detectors 1010. In addition, n×m photo detectors defined by X1, X2, X3, . . . , and Xn and Y1, Y2, Y3, . . . , and Ym may be a photo detector which is a part of the two-dimensionally arranged photo detectors 1010.

A material of a photo diode to be used in the two-dimensionally arranged photo detectors 1010 can be selected in accordance with a wavelength of the light to be detected. In order to excite an electron and a hole by light which is incident to the two-dimensionally arranged photo detectors 1010, a band gap energy of the material has to be lower than the energy of the incident light having the selected wavelength.

In the two-dimensionally arranged photo detectors 1010, as an example, a Si photo diode array corresponding to about 0.5 to 1.0 μm of an optical wavelength can be used. In addition, in the two-dimensionally arranged photo detectors 1010, as another example, an InGaAs/GaAs photo diode array or an InGaAS photo diode array corresponding to about 0.8 to 1.7 μm of the optical wavelength. In addition, in the two-dimensionally arranged photo detectors 1010, as still another example, a Ge photo diode array corresponding to about 0.8 to 1.7 μm of the optical wavelength.

In addition, in the two-dimensionally arranged photo detectors 1010, a charge coupled device (CCD) sensor or a complementary metal oxide semiconductor (CMOS) sensor which is used in a camera or the like can be used. In these sensors, for example, each pixel is about several micrometers and it corresponds to about 0.5 to 1.0 μm of the optical wavelength. By using these sensors that are general-purpose components to the two-dimensionally arranged photo detectors 1010, it is possible to obtain reduction in a manufacturing cost of the device.

The case where the two-dimensionally arranged photo detectors 1010 are used in the detection unit 121 is described. The detection unit 121 is not limited to the two-dimensionally arranged photo detectors 1010 and can be obtained using various photo sensors. For example, by moving one-dimensionally arranged photo detectors (line sensor) in which a plurality of photo detectors are arranged in one-dimensionally in one-dimensional direction orthogonal to an photo detector sequence, the detection unit 121 may be implemented by a device which is capable of detecting each power two-dimensionally arranged. In addition, by moving one photo detector in a two-dimensional direction, the detection unit 121 may be implemented by a device which is capable of detecting each power two-dimensionally arranged.

Radiation of LD (Normal Article) to Two-Dimensionally Arranged Photo Detectors According to Embodiment

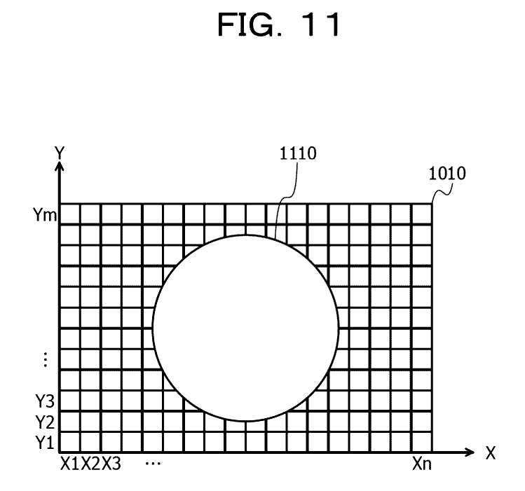

FIG. 11 is a diagram illustrating an example of a radiation of the LD (the normal article) to the two-dimensionally arranged photo detectors according to the embodiment. A spot 1110 illustrated in FIG. 11 is a spot of a laser beam radiated from the LD 110 that is a normal article in which the crystal defect does not occur to the two-dimensionally arranged photo detectors 1010. As illustrated in FIG. 11, the two-dimensionally arranged photo detectors 1010 has a pitch of each photo detector smaller than the spot 1110 are used such that the light is received to the spot 1110 on the plurality of photo detectors among the two-dimensionally arranged photo detectors 1010.

Detection Result of Two-Dimensional Output Power Distribution of LD (Normal Article) According to Embodiment

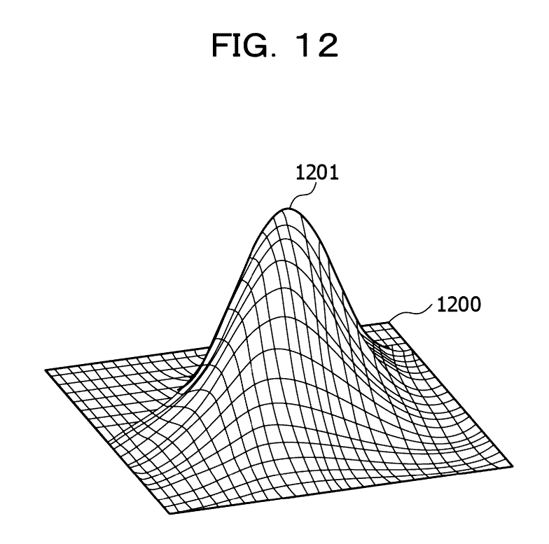

FIG. 12 is a diagram illustrating an example of a detection result of a two-dimensional output power distribution of the LD (the normal article) according to the embodiment. A two-dimensional output power distribution 1200 illustrated in FIG. 12 indicates a distribution of the optical power detected by the two-dimensionally arranged photo detectors 1010 in a case where the light is radiated from the LD 110 that is a normal article in which the crystal defect does not occur to the two-dimensionally arranged photo detectors 1010. In the two-dimensional output power distribution 1200, one peak 1201 is present.

Radiation of LD (Crystal Defect Generated Article) to Two-Dimensionally Arranged Photo Detectors According to Embodiment

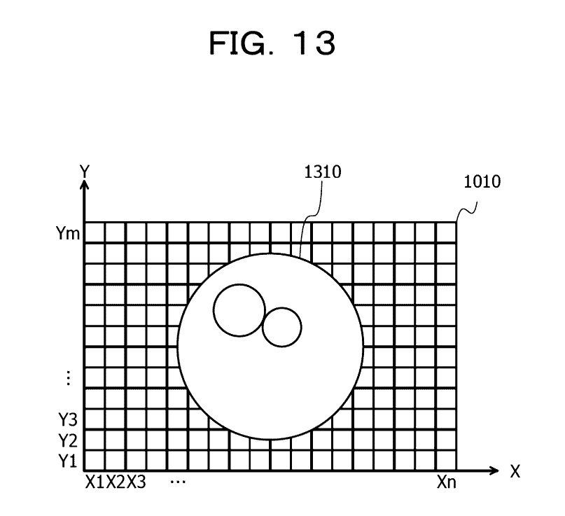

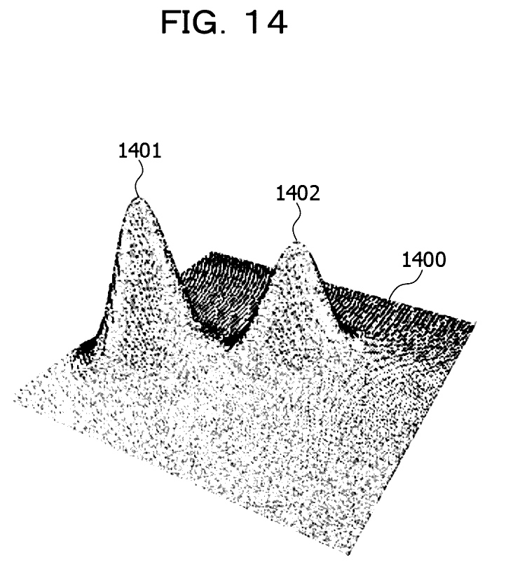

FIG. 13 is a diagram illustrating an example of a radiation of the LD (the crystal defect generated article) to the two-dimensionally arranged photo detectors according to the embodiment. In FIG. 13, same reference numerals are used for denoting the same portion as the portion of FIG. 11 and descriptions thereof will not be described. A spot 1310 illustrated in FIG. 13 is a spot of a laser beam radiated from the LD 110 where the crystal defect occurs to the two-dimensionally arranged photo detectors 1010. In the spot 1310, two peaks of the power are present (for example, refer to FIG. 14).

Detection Result of Two-Dimensional Output Power Distribution of LD (Crystal Defect Generated Article) According to Embodiment

FIG. 14 is a diagram illustrating an example of a detection result of the two-dimensional output power distribution of the LD (the crystal defect generated article) according to the embodiment. A two-dimensional output power distribution 1400 illustrated in FIG. 14 indicates a distribution of the optical power detected by the two-dimensionally arranged photo detectors 1010 in a case where the light is radiated from the LD 110 where the crystal defect occurs to the two-dimensionally arranged photo detectors 1010, as illustrated in FIG. 13, for example. In the two-dimensional output power distribution 1400, two peaks 1401 and 1402 are present.

As the two-dimensional output power distribution 1400, when a plurality of peaks appear in the two-dimensional output power distribution of the LD 110, it can be determined that there is a sign of the sudden death failure in the LD 110. Therefore, the determination unit 122 can determine the sudden death failure sign of the LD 110 based on the number of peaks in the two-dimensional output power distribution of the LD 110.

In addition, the determination unit 122 is not limited to the number of peaks in the two-dimensional output power distribution of the LD 110, and can determine the sudden death failure sign of the LD 110 based on the variation (for example, the deformation type from the gauss distribution) of the two-dimensional output power distribution of the LD 110.

Calculation of Two-Dimensional Output Power Distribution Based on Two-Dimensional Gauss Distribution

A calculation of the two-dimensional output power distribution based on a two-dimensional gauss distribution by the determination unit 122 will be described. By least square approximation fitting by the two-dimensional gauss distribution (bivariate normal distribution formula) with respect to the two-dimensional gauss distribution detected by the detection unit 121, a fitting coefficient or a correlation frequency can be calculated by the determination unit 122.

For example, the two-dimensional output power distribution detected by the detection unit 121 can approximated by the bivariate normal distribution formula represented Expression (1) below as an operation process using the bivariate normal distribution formula, for example.

$$f ( x , y ) = \frac{1}{2 * π * σ x * σ y \sqrt{1 - {ρ}^{2}}} * {e}^{\frac{1}{2 ( 1 - {ρ}^{2} )} \{ \frac{{( x - μ x )}^{2}}{σ {x}^{2}} - 2 ρ \frac{( x - μ x ) ( x - μ {y}^{2} )}{σ x * σ y} + \frac{{( y - μ y )}^{2}}{σ {y}^{2}} \}} \qquad ( 1 )$$

In addition, a correlation coefficient can be represented by Expression (2) below.

$$\frac{ρ * σ x * σ y}{\sqrt{σ {x}^{2} * σ {y}^{2}}} = ρ \qquad ( 2 )$$

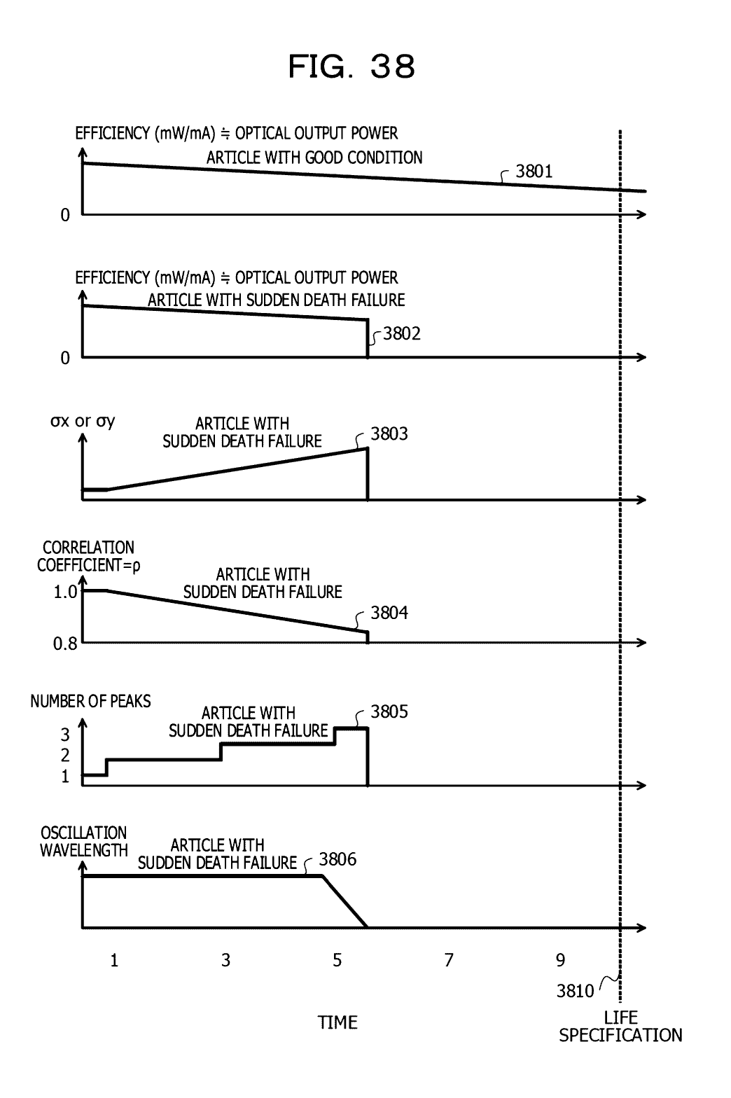

The determination unit 122 calculates the fitting coefficient (for example, σx or σy) or a correlation coefficient ρ by Expression (1) above or Expression (2) above. For example, in a case where there is the sudden death failure sign in the LD 110, a confinement of light in the LD 110 becomes weakened and the two-dimensional output power distribution (distribution area) becomes wider. Accordingly, σx or σy becomes gradually greater than the initial value (for example, refer to FIG. 38). In addition, in a case where there is the sudden death failure sign in the LD 110, the two-dimensional output power distribution is not in a guassian-shaped. Accordingly, the correlation coefficient ρ becomes gradually smaller than the initial value 1.

Accordingly, the determination unit 122 periodically monitors σx or σy, for example, and can determine that there is the sudden death failure sign of the LD 110 in a case where σx or σy exceeds a threshold value. In the threshold value to be compared with σx or σy, a value in which a certain value is added to the initial value of σx or σy can be used. However, the threshold value to be compared with σx or σy is not limited thereto and, for example, a predetermined fixed value may be used.

In addition, the determination unit 122 periodically monitors the correlation coefficient ρ, for example, and can determine that there is the sudden death failure sign of the LD 110 in a case where the correlation coefficient ρ is less than threshold value. In the threshold value to be compared with the correlation coefficient ρ, a value in which a certain value is added to the initial value of the correlation coefficient ρ can be used. However, the threshold value to be compared with the correlation coefficient ρ is not limited thereto and, for example, a predetermined fixed value may be used.

In addition, the determination unit 122 performs a low pass filter operation process with respect to the two-dimensional output power distribution detected by the detection unit 121. According to this, a fine variation of the optical power caused due to an interference or the like can be reduced. The determination unit 122 performs a differential operation process with respect to the two-dimensional output power distribution which is subjected to the low pass filter operation process. According to this, the number of changes in a slope of the two-dimensional output power distribution detected by the detection unit 121 can be calculated.

The number of changes in the slope of the two-dimensional output power distribution indicates the number of peaks of the number of the changes in the slope of the two-dimensional output power distribution. For example, the determination unit 122 periodically monitors the number of peaks of the two-dimensional output power distribution and can determine that there is the sudden death failure sign of the LD 110 in a case where the number of the peaks of the two-dimensional output power distribution exceeds the threshold value. The threshold value to be compared with the number of peaks can be set to 1, for example. In this case, it is determined that there is the sudden death failure sign in a case where the number of the peaks becomes the plural numbers. In addition, in a case where the number of the peaks of the two-dimensional output power distribution is the plural numbers in an initial state, the threshold value to be compared with the number of the peaks may be set to two or more value. In addition, the threshold value to be compared with the number of the peaks may be the initial value of the number of the peaks, or a value in which a certain number is added to the initial value of the number of the peaks.

The above-described fitting coefficient (σx, σy), the correlation coefficient ρ, and the number of peaks are feature values indicating a shape of the two-dimensional output power distribution which is changed in a case where there is the sudden death failure sign of the LD 110. These feature values are unaffected in the peak position of the two-dimensional output power distribution. By monitoring the changes in at least one of these feature values, the determination unit 122 can determine the sudden death failure sign of the LD 110.

For example, when the difference between the feature values and the predetermined value (for example, the initial value) and the initial value of the LD 110 is equal to or more than the certain amount, the determination unit 122 determines that there is the sudden death failure sign of the LD 110.

In addition, in a case of using a plurality of feature values, the determination unit 122 determines that there is the sudden death failure sign of the LD 110, for example, in a case where the difference between the feature value of the initial value of the at least one of the plurality of feature amounts is equal to or more than the certain value. According to this, it is possible to suppress a determination omission of the sudden death failure sign of the LD 110.

In addition, in a case of using the plurality of feature values, the determination unit 122 determines that there is the sudden death failure sign of the LD 110, for example, in a case where the difference between the plurality of feature values (for example, the entire feature values) and the initial value of the at least one of the plurality of feature amounts is equal to or more than the certain value. According to this, it is possible to suppress the detection omission of the sudden death failure sign of the LD 110.

In addition, the feature amount to be used in the determination of the sudden death failure sign of the LD 110 is not limited to the above-described fitting coefficient such as σx or σy, the correlation coefficient ρ, and the number of peaks, and can be set to various types of the feature values of the two-dimensional output power distribution which is changed in a case where there is the sudden death failure sign of the LD 110.

Output Power Distribution of LD (Normal Article) in X-Axis Direction According to Embodiment

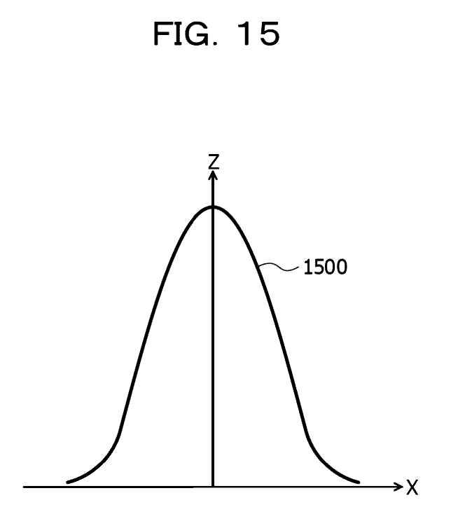

FIG. 15 is a diagram illustrating an example of the output power distribution of the LD (the normal article) in an X-axis direction according to the embodiment. In FIG. 15, a X-axis of the horizontal axis indicates a X-axis direction of the two-dimensionally arranged photo detectors 1010 and the Z-axis of the vertical axis indicates the optical power. A output power distribution 1500 illustrated in FIG. 15 indicates a output power distribution which is approximated in the X-direction based on the two-dimensional gauss distribution for the LD 110 that is the normal article in which the crystal defect does not occur. The output power distribution 1500 is a one-dimensional gauss distribution having one peak.

Output Power Distribution of LD (Normal Article) in Y-Axis Direction According to Embodiment

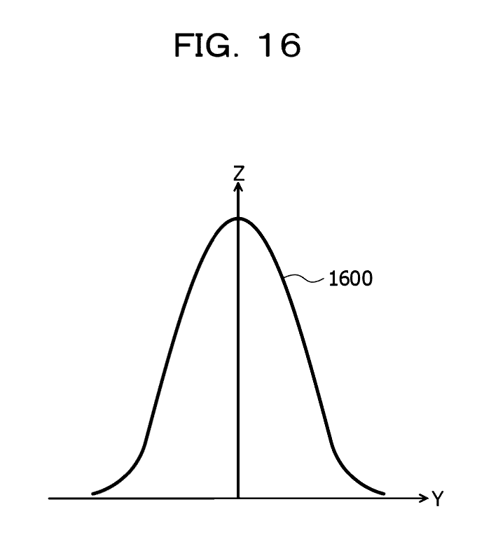

FIG. 16 is a diagram illustrating an example of the output power distribution of the LD (the normal article) in a Y-axis direction according to the embodiment. In FIG. 16, Y-axis of the horizontal axis indicates a Y-axis direction of the two-dimensionally arranged photo detectors 1010 and the Z-axis of the vertical axis indicates the optical power. A output power distribution 1600 illustrated in FIG. 16 indicates a output power distribution which is approximated in the Y-direction based on the two-dimensional gauss distribution for the LD 110 that is the normal article in which the crystal defect does not occur. The output power distribution 1600 is a one-dimensional gauss distribution having one peak.

Information to be Stored in Determination Unit According to Embodiment

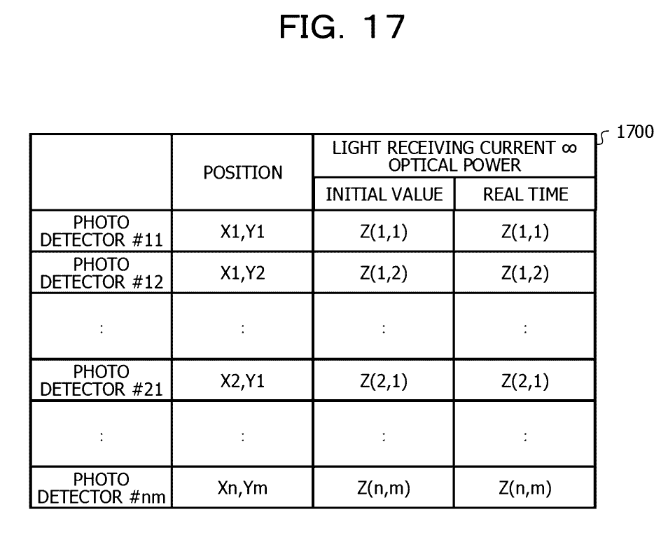

FIG. 17 is a diagram illustrating an example of information to be stored in a determination unit according to the embodiment. The determination unit 122 according to the embodiment stores a table 1700 illustrated in FIG. 17 in a memory of the determination device based on the detection result from the detection unit 121. The table 1700 indicate information which associates a position, an initial value of a light receiving current (that is, optical power), and a real time value of the light receiving current (that is, optical power) for each n×m photo detectors (the photo detector #11 to the photo detector nm) of two-dimensionally arranged photo detectors 1010.

Positions (X1, Y1), (X1, Y2), (X2, Y1), . . . , and (Xn, Ym) indicate positions of the corresponding photo detectors by a coordinate on a XY plane of the two-dimensionally arranged photo detectors 1010. The initial value of the light receiving current is a light receiving current detected by the photo detectors corresponding to a case where an operation of the LD 110 is started. The real time value of the light receiving current is the latest light receiving current detected by the photo detectors corresponding to during operation of the LD 110.

The determination unit 122 calculates the two-dimensional output power distribution of the LD 110 in a case where the operation of the LD 110 is started as an initial two-dimensional output power distribution, based on the initial value of the light receiving current corresponding to each of the photo detectors of the two-dimensionally arranged photo detectors 1010. In addition, the determination unit 122 calculates the two-dimensional output power distribution of the LD 110 as a two-dimensional output power distribution of the real time, based on the real time value of the light receiving current corresponding to each of the photo detectors of the two-dimensionally arranged photo detectors 1010. The determination unit 122 periodically calculates the two-dimensional output power distribution of the real time to update.

The determination unit 122 determines the sudden death failure sign of the LD 110 based on the calculated initial two-dimensional output power distribution and the two-dimensional output power distribution of the real time. As an index of the determination by the determination unit 122, for example, the above-described least square approximation fitting of the two-dimensional gauss distribution can be used. In this case, for example, by comparing the initial value and the real time value for the above-described fitting coefficient or the correlation coefficient, it is possible to determine the sudden death failure sign of the LD 110. In addition, as the index of the determination by the determination unit 122, for example, the above-mentioned low pass filter operation process and the differential operation process can be used. In this case, by comparing the initial value and the real time value for the number of changes in the slopes of the two-dimensional output power distribution, it is possible to determine the sudden death failure sign of the LD 110.

Optical Transmission Device on which LDs are Mounted at High Density According to Embodiment

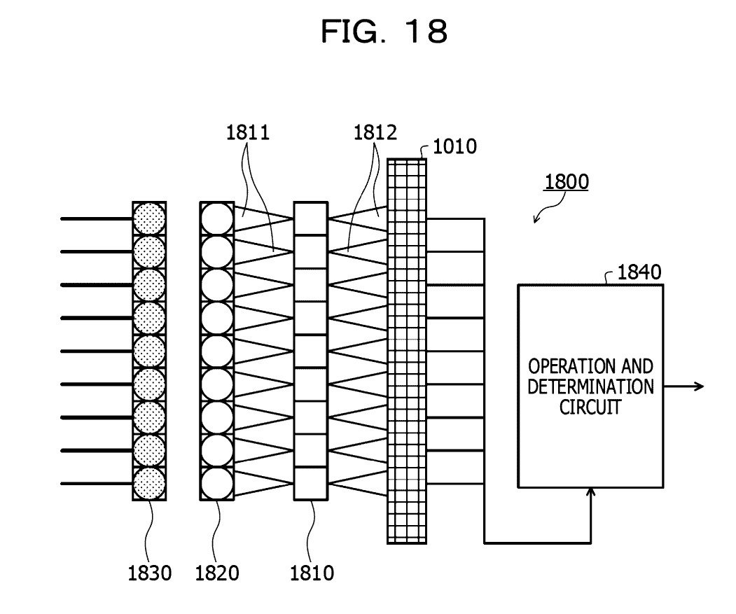

FIG. 18 is a diagram illustrating an example of an optical transmission device on which the LDs are mounted at a high density according to the embodiment. The laser device 100 according to the embodiment can be implemented by, for example, an optical transmission device 1800 illustrated in FIG. 18. The optical transmission device 1800 includes an LD array 1810, a lens array 1820, a multi-mode ribbon fiber 1830, the two-dimensionally arranged photo detectors 1010, and an operation and determination circuit 1840.

The above-described LD 110 can be implemented by the LD array 1810, for example. The above-described detection unit 121 can be implemented by the two-dimensionally arranged photo detectors 1010 and the operation and determination circuit 1840, for example. The above-described determination unit 122 can be implemented by the operation and determination circuit 1840.

The LD array 1810 is an LD array in which a plurality of LDs (nine LDs in FIG. 18) is arranged in an array shape. A front emission light 1811 is a laser beam (front light) emitted from the front of each LD of the LD array 1810. A back emission light 1812 is a laser beam (back light) emitted from the front of each LD of the LD array 1810.

The lens array 1820 is a lens array in which a plurality of lens is arranged in an array shape. Each lens of the lens array 1820 is provided corresponding to each LD of the LD array 1810 and condenses the front emission light 1811 emitted from each LD of the LD array 1810.

The multi-mode ribbon fiber 1830 is a multi-mode ribbon fiber in which a multi-mode ribbon fiber is arranged in a ribbon shape. Each multi-mode optical fiber of the multi-mode ribbon fiber 1830 is provided corresponding to each lens of the lens array 1820 and transmits the front emission light 1811 which is condensed by each lens of the lens array 1820.

The two-dimensionally arranged photo detectors 1010 is the two-dimensionally arranged photo detectors 1010 illustrated in FIG. 10, for example, and is a photo detector array in which the photo detectors is arranged in a two-dimensionally with high density by each LD of the LD array 1810. Each photo detector of the two-dimensionally arranged photo detectors 1010 receives the back emission light 1812 emitted from the LD array 1810 and output the light receiving current indicating the power of the received back emission light 1812 to the operation and determination circuit 1840.

The operation and determination circuit 1840 determines the sudden death failure sign of the LD included in the LD array 1810, based on the light receiving current output from each photo detector of the two-dimensionally arranged photo detectors 1010. For example, when it is determined that there is the sudden death failure sign of the LD included in the LD array 1810, the operation and determination circuit 1840 notifies an outside of the effect. The outside means, for example, a maintenance person or a control device for controlling the optical transmission device 1800.

Another Example of Two-Dimensionally Arranged Photo Detectors Included in Detection Unit According to Embodiment

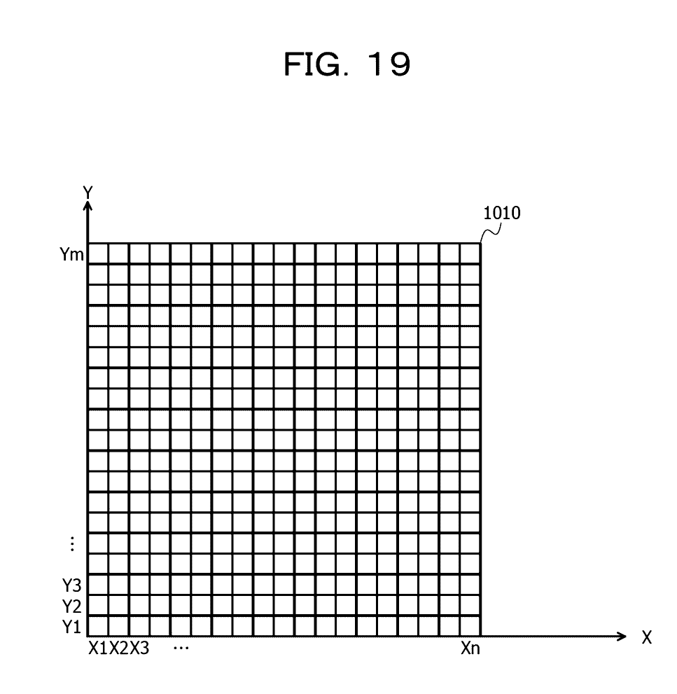

FIG. 19 is a diagram illustrating another example of the two-dimensionally arranged photo detectors included in the detection unit according to the embodiment. In FIG. 19, same reference numerals are used for denoting the same portion as the portion of FIG. 10 and descriptions thereof will not be described. In a case where the sudden death failure sign is determined for each LD of the LD array 1810 as illustrated in FIG. 18, the two-dimensionally arranged photo detectors 1010 in the above-described detection unit 121 may include a lot of the photo detector as the two-dimensionally arranged photo detectors 1010 illustrated in FIG. 19, for example. According to this, each laser beam emitted from the plurality of LDs can be received.

Radiation of a Plurality of LDs (Normal Article) to Two-Dimensionally Arranged Photo Detectors According to Embodiment

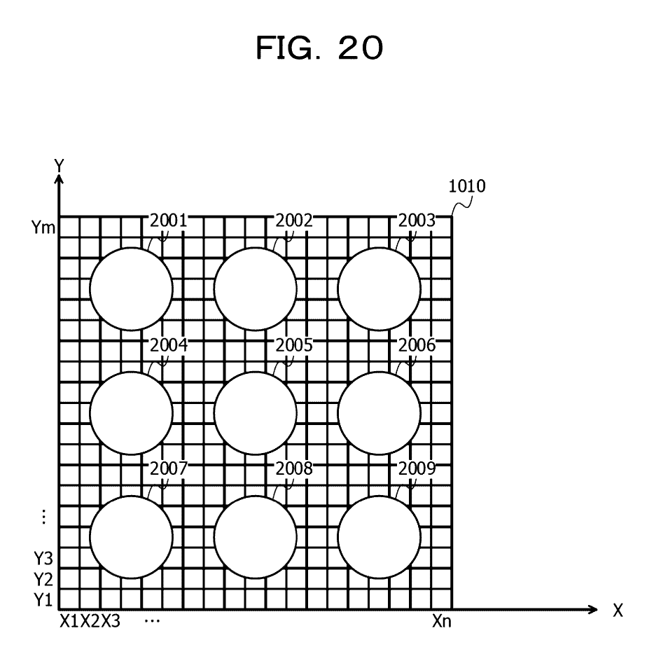

FIG. 20 is a diagram illustrating an example of a radiation of a plurality of LDs (normal articles) to the two-dimensionally arranged photo detectors according to the embodiment. Spots 2001 to 2009 illustrated in FIG. 20 are a spot of each laser beam radiated from each LD (normal article) of the LD array 1810 illustrated in FIG. 18 to the two-dimensionally arranged photo detectors 1010 illustrated in FIG. 19.

In the example illustrated in FIG. 20, by arranging nine LDs in the LD array 1810 in 3×3 two-dimensional shape, the spots 2001 to 2009 are also 3×3 two-dimensional shaped position. However, the disposition of each LD in the LD array 1810 is not limited thereto and may be, for example, a one-dimensional shaped position.

In this case, the operation and determination circuit 1840 (determination unit) calculates the two-dimensional output power distribution and the total power for each of the LDs, based on the power in each position of the two-dimensionally arranged photo detectors 1010 detected by the two-dimensionally arranged photo detectors 1010 (detection unit). The operation and determination circuit 1840 determines the sudden death failure sign for each LDs, based on the calculated power distribution and the total power. According to this, the sudden death failure sign of the plurality of LDs can be determined based on the detection result in each position by the two-dimensionally arranged photo detectors 1010.

Another Example of Information to be Stored in Determination Unit According to Embodiment

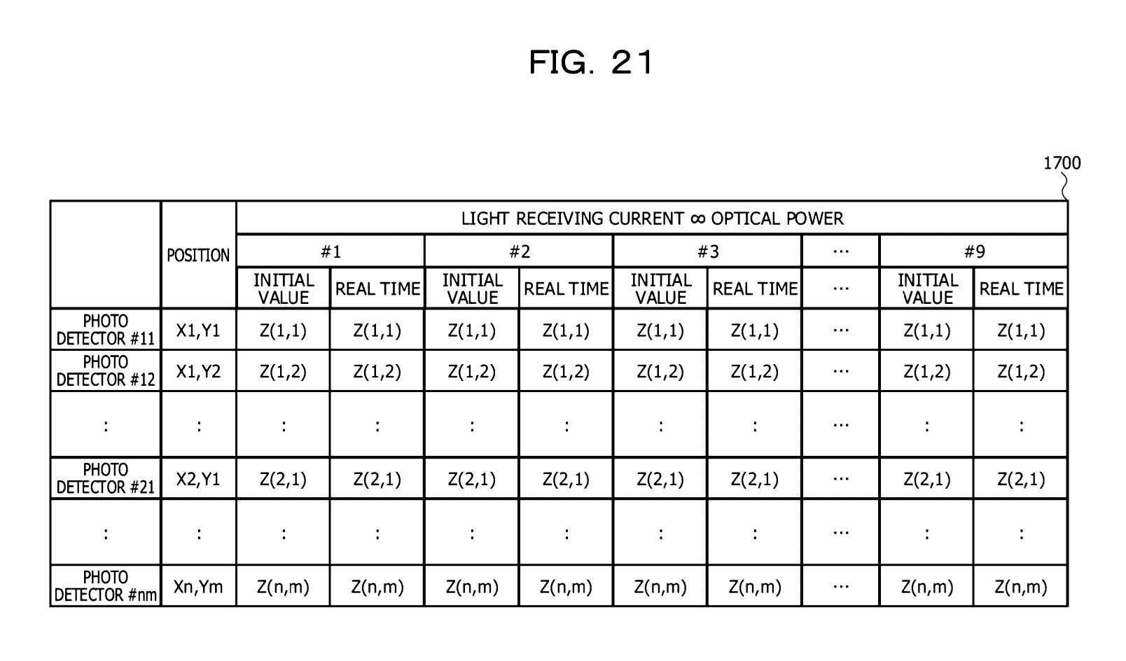

FIG. 21 is a diagram illustrating another example of the information to be stored in the determination unit according to the embodiment. In a case where the sudden death failure sign is determined for each LD of the LD array 1810 as illustrated in FIG. 18, the determination unit 122 stores the table 1700 illustrated in FIG. 21 to a memory of the laser device 100, for example, based on the detection result from the detection unit 121.

In the table 1700 illustrated in FIG. 21, the initial value of the light receiving current and the real time value are associated with each other for each of the spots 2001 to 2009 illustrated in FIG. 20. By using a light receiving result obtained by a plurality of photo detectors which is formed into one-chip manner (the two-dimensionally arranged photo detectors 1010), the determination unit 122 monitors the optical power distribution for each LD of the LD array 1810 to determine the sudden death failure sign.

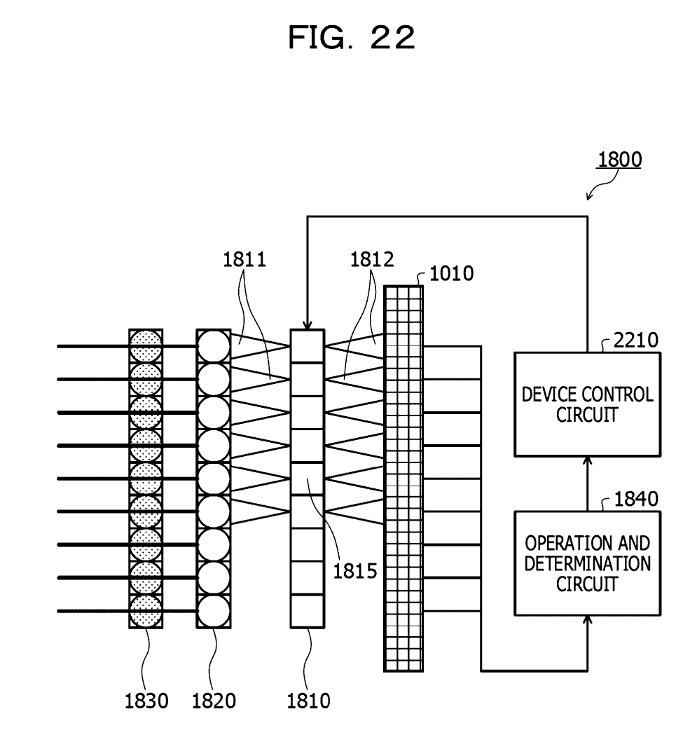

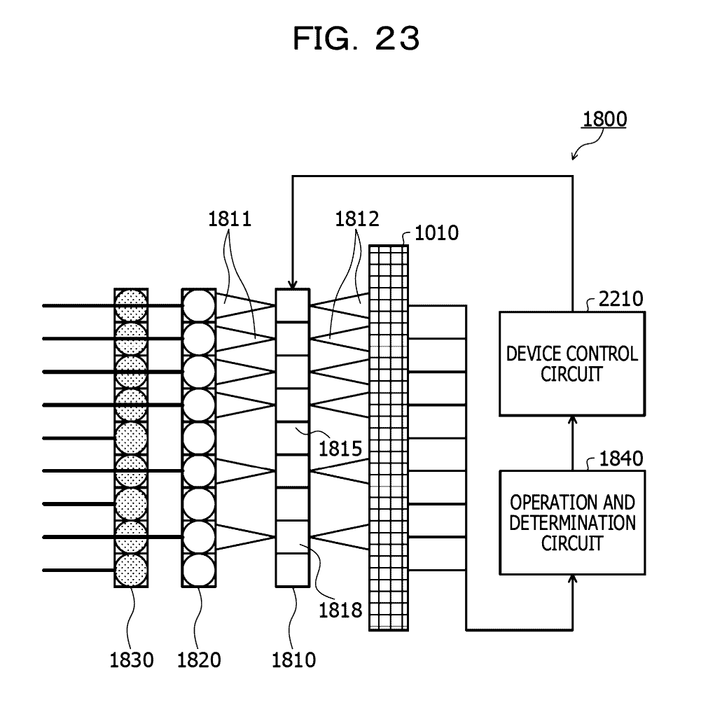

LD Switching based on Detection Result according to Embodiment FIGS. 22 and 23 are diagrams illustrating an example of an LD switching based on a detection result of a determination device according to the embodiment. In FIGS. 22 and 23, same reference numerals are used for denoting the same portion as the portion of FIG. 18 and descriptions thereof will not be described. As illustrated in FIGS. 22 and 23, the optical transmission device 1800 may include a device control circuit 2210 in addition to the configuration illustrated in FIG. 18. The operation and determination circuit 1840 notifies the device control circuit 2210 of the determination result of the sudden death failure sign of the LD included in the LD array 1810.

For example, in at a time when an operation of the optical transmission device 1800 is started, it is assume that six lines are operated, first to sixth LDs (six LDs in an upper side of the drawings) in the LD array 1810 is set to an operation system. In addition, it is assumed that seventh to ninth LDs (three LDs in a lower side of the drawings) in the LD array 1810 is set as a standby system.

In this case, the device control circuit 2210 performs a control of emitting the first to sixth LDs in the LD array 1810 and quenching the seventh to ninth LDs in the LD array 1810, as illustrated in FIG. 22. In addition, when it is determined that there is the sudden death failure sign of the LD included in the LD array 1810 by the operation and determination circuit 1840, the device control circuit 2210 performs a control of switching the LD used in the line using the LD to the LD of the standby system.

In a state illustrated in FIG. 22, it is assumed that the operation and determination circuit 1840 determines that there is the sudden death failure sign of a fifth LD 1815 based on the two-dimensional output power distribution of the LD 1815 in the LD array 1810.

In this case, the device control circuit 2210 switches the LD to be used in the line using the LD 1815 to an eighth LD 1818 set in the standby system as illustrated in FIG. 23, for example. The device control circuit 2210 is configured to turn off the LD 1815 which is determined that there is the sudden death failure sign. According to this, it is possible to perform switching from the LD 1815 which is determined that there is the sudden death failure sign to the LD 1818.

Change in Spot by LD Switching According to Embodiment

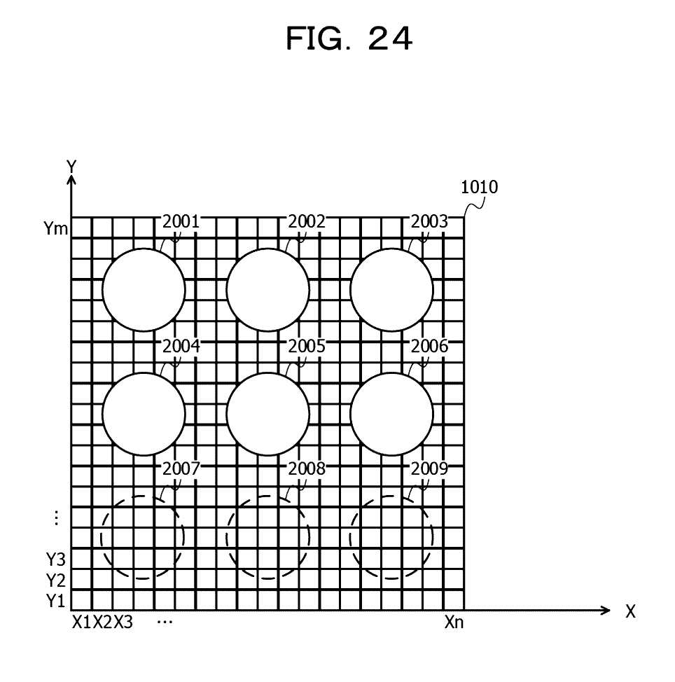

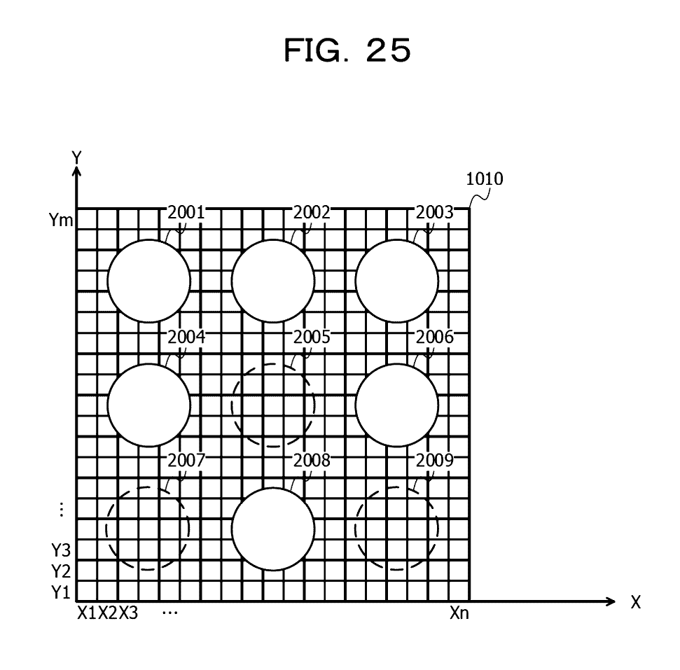

FIGS. 24 and 25 are diagrams illustrating an example of a change in a spot due to the LD switching according to the embodiment. In FIGS. 24 and 25, same reference numerals are used for denoting the same portion as the portion of FIG. 20 and descriptions thereof will not be described. For example, as illustrated in FIG. 22, it is assume that the first to sixth LDs in the LD array 1810 are set to the operation system, and the seventh to ninth LDs in the LD array 1810 are set to the standby system.

In this case, as illustrated in FIG. 24, the spots 2001 to 2006 are radiated to the two-dimensionally arranged photo detectors 1010 and the spots 2007 to 2009 are not radiated. In this state, the operation and determination circuit 1840 determines that there is the sudden death failure sign of the LD 1815 of the LD array 1810 based on the two-dimensional output power distribution of the spot 2005.

In this case, as illustrated in FIG. 23, the device control circuit 2210 switches the LD used in the line using the LD 1815 to the eighth LD 1818 which is set to the standby system, for example. The operation and determination circuit 1840 turns off the LD 1815 which is determined that there is the sudden death failure sign. According to this, as illustrated in FIG. 25, the spot 2008 is newly radiated to the two-dimensionally arranged photo detectors 1010 and the spot 2005 becomes not radiated.

As illustrated in FIGS. 22 to 25, the optical transmission device 1800 sets the standby (lengthy) LD is set in the LD array 1810 in advance and receives the optical output power of each LD in accordance with the number of arrays, at once, by the two-dimensionally arranged photo detectors 1010. The optical transmission device 1800 performs operation processing (mapping) of a monitor current value of each photo detector of the two-dimensionally arranged photo detectors 1010 to monitor the optical output power and a far field pattern.

The optical transmission device 1800 early and autonomously determines a sign of the sudden death failure during the stable LD operation using a change in the optical power distribution as a determination reference, based on the monitor result. The optical transmission device 1800 switches the LD which is determined that there is the sudden death failure sign to a standby LD during the stable LD operation. According to this, even without power shutting down the device, it is possible to perform a stable operation.

Process by Optical Transmission Device According to Embodiment

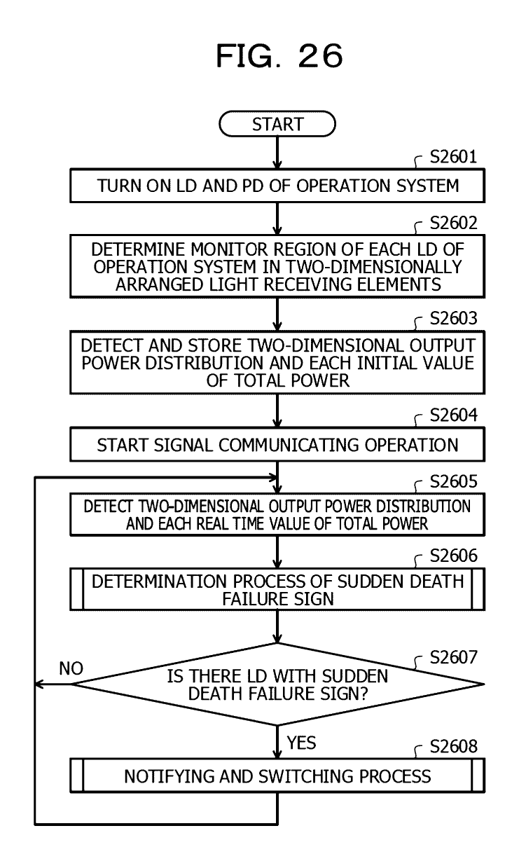

FIG. 26 is a flow chart illustrating an example of a process by the optical transmission device according to the embodiment. For example, the optical transmission device 1800 according to the embodiment executes each step illustrated in FIG. 26. First, the optical transmission device 1800 turns of the LD and PD of the operation system (step S2601). In step S2601, for example, the optical transmission device 1800 turns of the LD of the operation system by starting input of the driving signal to the LD of the operation system among each of the LDs of the LD array 1810 of the device. In this time, the light emitted from the LD of the operation system may be a signal for a test without the signal light.

In addition, in step S2601, the optical transmission device 1800 performs controlling the PD corresponding to the LD of the operation system among each of PDs of the optical transmission device at the receiving side facing the device into a state (turns on) where the laser beam can be received. The controlling can be performed by transmitting a control signal to the optical transmission device at the receiving side by the optical transmission device 1800, for example.

Next, the optical transmission device 1800 determines a monitoring region of each LD of the operation system of the LD array 1810 in the two-dimensionally arranged photo detectors 1010 (step S2602). A determination method of the monitoring region of each LD in step S2602 will be described below.

Next, the optical transmission device 1800 detects each initial value of the two-dimensional output power distribution and the total power for each of LDs of the operation system, based on the detection result of the monitoring region of each LD of the operation system determined in step S2602 (step S2603). The optical transmission device 1800 stores each initial value of the detected two-dimensional output power distribution and the total power to the memory. For example, the detection of the two-dimensional output power distribution can be performed by calculating the above-described fitting coefficient (σx, σy), the correlation coefficient ρ, and the number of peaks. For example, the detection of the total power can be performed by calculating a total values of the optical power detected by the monitoring region determined in step S2602 for the corresponding LD.

Next, the optical transmission device 1800 starts a signal communicating operation (step S2604). For example, the optical transmission device 1800 starts the signal communicating operation by input a driving signal based on data of a transmission target to each LD of the operation system.

Next, the optical transmission device 1800 detects each real time value of the two-dimensional output power distribution and the total power for each LD of the operation system, based on the detection result of the monitoring region of each LD of the operation system which is determined in step S2602 (step S2605).

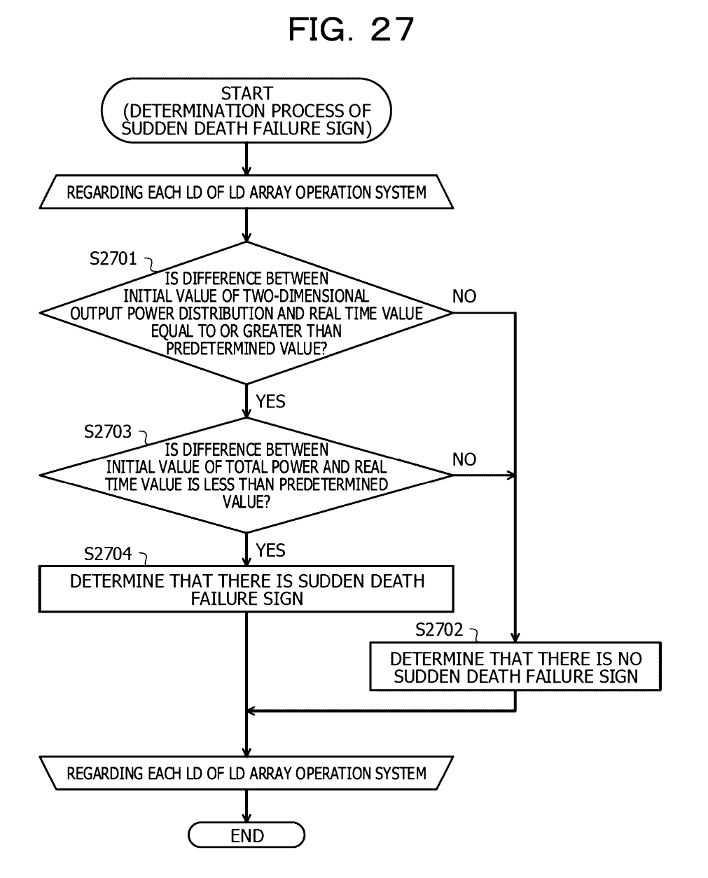

Next, the optical transmission device 1800 performs a determination process of a predetermined sudden death failure sign based on each initial value which is detected in step S2603 and stored and each latest real time value detected in step S2605 (step S2606). The determination process of the sudden death failure sign in step S2606 will be described below (for example, refer to FIG. 27).

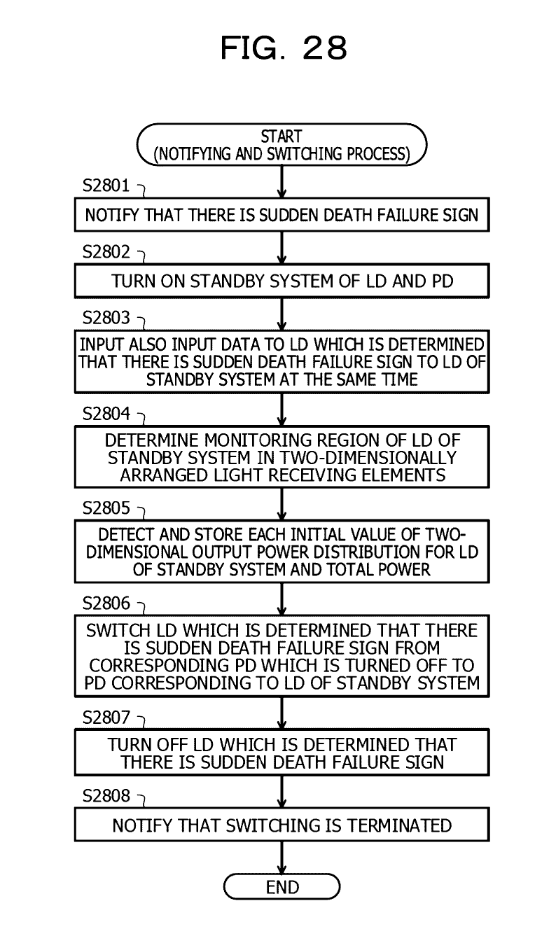

Next, the optical transmission device 1800 determines whether there is the LD with the sudden death failure sign in each LD of the operation system based on the result of the determination process of the sudden death failure sign in step S2606 (step S2607). In a case where there is no LD with the sudden death failure sign (step S2607: No), the optical transmission device 1800 returns to step S2605. In a case where there is the LD with the sudden death failure sign (step S2607: Yes), the optical transmission device 1800 performs a predetermined notifying and switching process (step S2608) and returns to step S2605. In step S2608, the predetermined notifying and switching process will be described below (for example, refer to FIG. 28).

Determination Method of Monitoring Region of Each LD

In step S2602, for example, the optical transmission device 1800 detects each region where the spot of each LD of the LD array 1810 is radiated as a monitoring region based on the detection result of the optical power by each photo detector of the two-dimensionally arranged photo detectors 1010.

As an example, the optical transmission device 1800 detects only the number of LDs of the operation system in order of higher optical power and determines the peak of the optical power in the two-dimensionally arranged photo detectors 1010 as a reference point of the monitoring region of each LD. The optical transmission device 1800 determines a certain range in which the reference point is used as a center for each reference point of the determined monitoring region.

Associating of each LD and each reference point can be performed by searching an assembly in which a distance between the center position and the reference point becomes minimized, among assemblies of each reference point and each center position in terms of deigns of the spot of each LD. However, the determination method of the monitoring region of each LD is not limited such a method, and can use various determination methods.

Determination Process of Sudden Death Failure Sign by Optical Transmission Device According to Embodiment

FIG. 27 is a flow chart illustrating an example of a determination process of the sudden death failure sign by the optical transmission device according to the embodiment. In step S2606 illustrated in FIG. 26, for example, the optical transmission device 1800 executes each step illustrated in FIG. 27 as a determination process of the sudden death failure sign. That is, the optical transmission device 1800 executes following each step using each LD of the operation system of the LD array 1810 as a target.

First, the optical transmission device 1800 determines whether a difference (absolute value) between the initial value and the real time value for the two-dimensional output power distribution of the target LD is equal to or greater than the predetermined value (step S2701). The initial value for the two-dimensional output power distribution of the target LD is the two-dimensional output power distribution which is detected and stored for the target LD in step S2603 illustrated in FIG. 26. The real time value for the two-dimensional output power distribution of the target LD is the latest two-dimensional output power distribution which is detected for the target LD in step S2605 illustrated in FIG. 26. The difference between the initial value and the real time value for the two-dimensional output power distribution can use, for example, a difference between the real time value and the initial value in at least one of the above-described fitting coefficient (σx, σy), the correlation coefficient ρ, and the number of peaks.

In step S2701, in a case where the difference is less than the predetermined value (step S2701: No), the optical transmission device 1800 determines that there is no sudden death failure sign in each LD of the operation system (step S2702), and terminates a serious of processes for the target LD.

In step S2701, in a case where the difference is equal to or greater than the predetermined value (step S2701: Yes), the optical transmission device 1800 proceeds to step S2703. That is, the optical transmission device 1800 determines whether the difference (absolute value) between the real time value and the initial value for the total power of the target LD is less than the predetermined value (step S2703). The initial value for the total power of the target LD is a total power which is detected and stored for the target LD in step S2603 illustrated in FIG. 26. The real time value for the total power of the target LD is the latest total power which is detected for the target LD in step S2605 illustrated in FIG. 26.

In step S2703, in a case where the difference is less than the predetermined value (step S2703: Yes), the optical transmission device 1800 determines that there is no sudden death failure sign in the target LD (step S2704), and terminates a serious of processes for the target LD. In a case where the difference is equal to or greater than the predetermined value (step S2703: No), the optical transmission device 1800 proceeds to step S2702.

According to this, for the target LD, even when a variation of the two-dimensional output power distribution is present, it is possible to determine that there is no sudden death failure sign in a case where a variation occurs greatly in the total power. According to this, for example, in a case where the variation of the two-dimensional output power distribution occurs, regardless of the sudden death failure of the LD by a disturbance due to a vibration in the optical transmission device 1800, it is possible to avoid an erroneous determination that there is the sudden death failure sign of the LD.

Notifying and Switching Process by Optical Transmission Device According to Embodiment

FIG. 28 is a flow chart illustrating an example of a notifying and switching process by the optical transmission device according to the embodiment. In step S2608 illustrated in FIG. 26, the optical transmission device 1800 executes each step illustrated in FIG. 28 as the notifying and switching process, for example.

First, the optical transmission device 1800 notifies the maintenance persons of the optical transmission device 1800 of information that there is the sudden death failure sign in the LD of the operation system (step S2801). In step S2801, the optical transmission device 1800 may notify the maintenance persons of identification information of the LD which is determined that there is the sudden death failure sign or information that the switching of the LD of the operation system is performed.

Next, the optical transmission device 1800 turns of the standby system of the LD and PD (step S2802). For example, in step S2802, the optical transmission device 1800 turns of the LD of the standby operation by starting input of the driving signal to the LD of the standby system among each of the LDs of the LD array 1810. In this time, the light emitted from the LD of the operation system may be a signal for a test without the signal light.

In addition, in step S2802, the optical transmission device 1800 performs controlling the PD of the standby system corresponding to the LD of the standby system among each of PDs of the optical transmission device at the receiving side facing the device into a state (turned on state) where the laser beam can be received. The controlling can be performed by transmitting a control signal to the optical transmission device at the receiving side by the optical transmission device 1800, for example.

Next, the optical transmission device 1800 processes to a state where input data to the LD which is determined that there is the sudden death failure sign in step S2606 illustrated in FIG. 26 is also input in the LD of standby LD which is turned on in step S2802 at the same time (step S2803).

Next, the optical transmission device 1800 determines the monitoring region of each LD of the standby system which is turned on in step S2802 in the two-dimensionally arranged photo detectors 1010 (step S2804). The determination of the monitoring region in the step S2804 is the same as the determination of the monitoring region in step S2602 illustrated in FIG. 26, for example.

Next, the optical transmission device 1800 detects each initial value of the two-dimensional output power distribution and the total power for each of LDs of the standby system, based on the detection result of the monitoring region of each LD of the standby system determined in step S2804 (step S2805). The optical transmission device 1800 stores each initial value of the detected two-dimensional output power distribution and the total power to the memory.

Next, the optical transmission device 1800 performs a control of switching the PD of the latest operation system to be used in the line using the LD which determined there is the sudden death failure sign to the PD which is turned on in step S2802 (step S2806). The controlling can be performed by transmitting the control signal to the optical transmission device at the receiving side by the optical transmission device 1800, for example.

Next, the optical transmission device 1800 turns off the LD which is determined that there is the sudden death failure sign (step S2807). In step S2807, for example, the optical transmission device 1800 turns off the LD by interrupting an input of the driving signal to the LD which is determined that there is the sudden death failure sign. Next, the optical transmission device 1800 notifies the maintenance persons of the optical transmission device 1800 of information that the switching of the LD and the PD of the operation system is terminated (step S2808), and terminates a serious of processes. In step S2808, the optical transmission device 1800 may notify the maintenance persons of the identification information of the LD or PD which is the switching destination.

The notifying and switching process in step S2608 is not limited to each step illustrated in FIG. 26. For example, the process may be a process without performing at least one of notifications of steps S2801 and S2808. In addition, without performing switches of the LD and the PD of the operation system in steps S2802 to S2807, only at least one process of the notifications in steps S2801 and S2808 may be performed. In this case, the maintenance person of the optical transmission device 1800 manually switches the LD and the PD of the operation system and performs a work such as stopping of the operation.

Optical Transmission System According to Embodiment

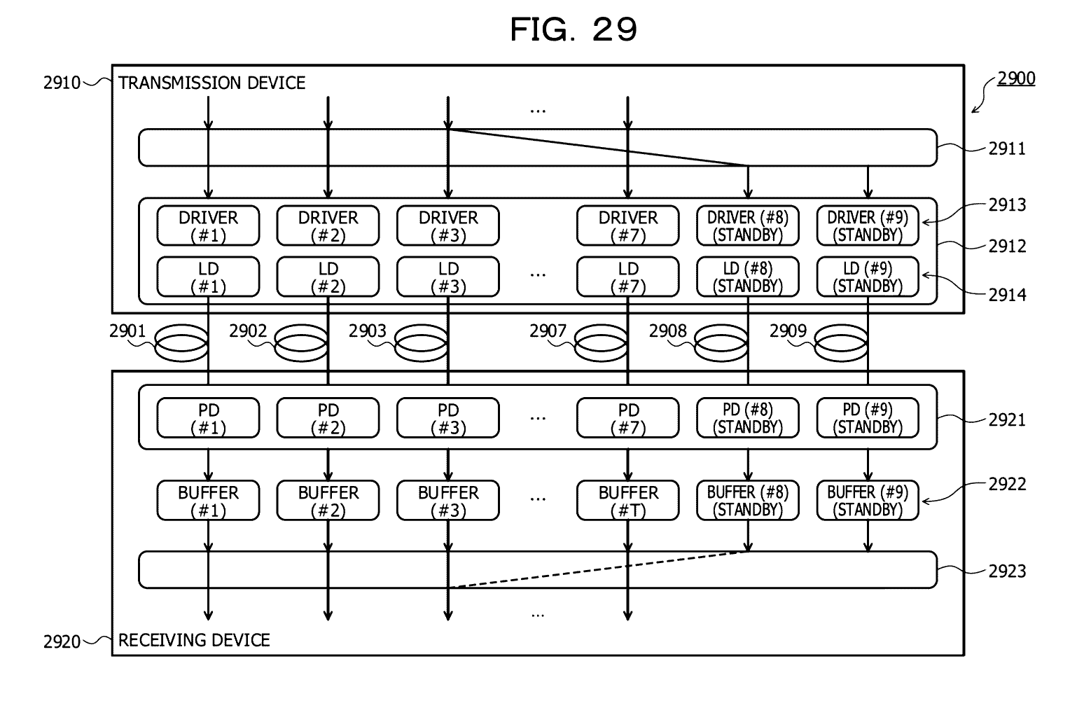

FIG. 29 is a diagram illustrating an example of an optical transmission system according to the embodiment. As illustrated in FIG. 29, a transmission system 2900 according to the embodiment includes a transmission device 2910 and a receiving device 2920. The transmission device 2910 includes a transmission side electrical switch 2911 and an LD array 2912. In the example illustrated in FIG. 29, a case where an optical line which is capable of allowing the optical signal to be transmitted is nine lines (#1 to #9) is described. However, the number of the optical lines is not limited to nine. The number of the optical lines can be set two or more of a certain number, for example.

The transmission side electrical switch 2911 outputs data to be transmitted which is input from a client to a certain driver among drivers 2913 (#1 to #9) of the LD array 2912. The LD array 2912 includes nine drivers 2913 (#1 to #9) and nine LDs 2914 (#1 to #9).

The drivers 2913 (#1 to #9) are provided corresponding to the LDs 2914 (#1 to #9), respectively. Each of the drivers 2913 (#1 to #9) output a driving signal in accordance with the data output from the transmission side electrical switch 2911 to the corresponding LD among the LDs 2914 (#1 to #9). For example, the driver 2913 (#1) outputs the driving signal in accordance with the data output from the transmission side electrical switch 2911 to the LD 2914 (#1). In addition, the driver 2913 (#2) outputs the driving signal in accordance with the data output from the transmission side electrical switch 2911 to the LD 2914 (#2).

The LDs 2914 (#1 to #9) have a configuration corresponding to each LD of the above-described LD array 1810. The LDs 2914 (#1 to #9) emit laser beams in accordance with the driving signals output from the drivers 2913 (#1 to #9) to the receiving device 2920 through optical fibers 2901 to 2909, respectively. For example, the LD 2914 (#1) emits the laser beam in accordance with the driving signal output from the driver 2913 (#1) to the receiving device 2920 through the optical fiber 2901. In addition, the LD 2914 (#2) emits the laser beam in accordance with the driving signal output from the driver 2913 (#2) to the receiving device 2920 through the optical fiber 2902.

The receiving device 2920 includes nine PDs 2921 (#1 to #9), nine buffers 2922 (#1 to #9), and a receiving side electrical switch 2923. The PDs 2921 (#1 to #9) receive laser beams emitted from the transmission device 2910 through the optical fibers 2901 to 2909.

The PDs 2921 (#1 to #9) output electrical signals in accordance with the receiving result of the laser beam to the buffers 2922 (#1 to #9), respectively. For example, the PD 2921 (#1) receives the laser beam emitted from the LD 2914 (#1) through the optical fiber 2901 and outputs the electrical signal indicating the receiving result to the buffer 2922 (#1). In addition, the PD 2921 (#2) receives the laser beam emitted from the LD 2914 (#2) through the optical fiber 2902 and outputs the electrical signal indicating the receiving result to the buffer 2922 (#2).

The buffers 2922 (#1 to #9) perform buffering the electrical signals output from the PDs 2921 (#1 to #9), respectively, by for enough time to switch the operation system to be described. Each of the buffers 2922 (#1 to #9) outputs the electrical signals subjected to the buffering to the receiving side electrical switch 2923. For example, the buffer 2922 (#1) performs buffering the electrical signal output from the PD 2921 (#1) and outputs the electrical signal subjected to the buffering to the receiving side electrical switch 2923. In addition, the buffer 2922 (#2) performs buffering the electrical signal output from the PD 2921 (#2) and outputs the electrical signal subjected to the buffering to the receiving side electrical switch 2923.

The receiving side electrical switch 2923 outputs the electrical signals output from the buffers 2922 (#1 to #9) to a certain processing unit among processing units of each line of the client.

In addition, it is not illustrated in drawings, and the transmission device 2910 includes, for example, the operation and determination circuit 1840 illustrated in FIG. 22 and the device control circuit 2210. The operation and determination circuit 1840 determines the sudden death failure signs of the LDs 2914 (#1 to #9). When the operation and determination circuit 1840 determines that there is the sudden death failure sign, the operation system is switched by the device control circuit 2210.

For example, in an initial state, it is assumed that the LDs 2914 (#1 to #7) and the PDs 2921 (#1 to #7) are set as the operation system and the LDs 2914 (#8 and #9) and the PDs 2921 (#8 and #9) are set as the standby system. In this state, the operation and determination circuit 1840 determines that there is the sudden death failure sign in the LD 2914 (#3) of the operation system.

In this case, as illustrated in FIG. 29, the device control circuit 2210 controls the transmission side electrical switch 2911 and copies data input in the LD 2914 (#3) to process the state of input to the LD 2914 (#8) of the standby system, for example. The device control circuit 2210 transmits the control signal to the receiving device 2920 to control the PD 2921 (#8) to be turned on. The transmission of the control signal from the device control circuit 2210 to the receiving device 2920 may be performed by at least one of the LDs 2914 during operation and may be performed by other lines.

In addition, the device control circuit 2210 performs a control of switching the receiving side electrical switch 2923 such that the electrical signal output from the buffer 2922 (#8) is output to the processing unit same as that of the electrical signal output from the buffers 2922 (#3). The controlling can be performed by transmitting a control signal to the receiving device 2920 at the receiving side by the device control circuit 2210, for example.

Next, it is not illustrated in drawings, the device control circuit 2210 performs a control of turning off the LD 2914 (#3) and turning off the PD 2921 (#3) by transmitting the control signal to the receiving device 2920. According to this, the LDs 2914 and the PDs 2921 of the operation system can be switched from the LD 2914 (#3) and the PD 2921 (#3) to the LD 2914 (#8) and the PD 2921 (#8).

Calculation of Output Power Distribution of LD According to Embodiment

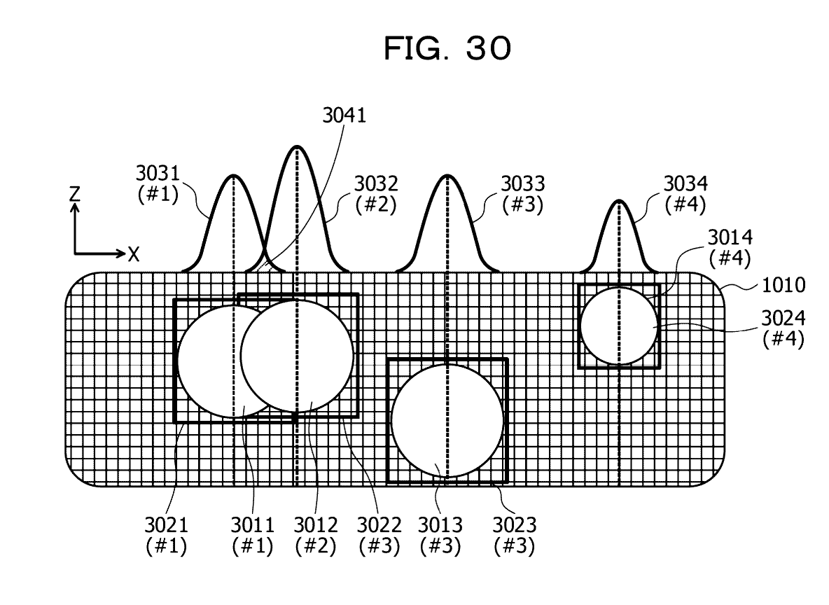

FIG. 30 is a diagram illustrating an example of a calculation of the output power distribution of each LD according to the embodiment. Spots 3011 to 3014 (#1 to #4) illustrated in FIG. 30 are spots of each laser beam radiated from four LDs (#1 to #4) of the LD array 1810 to the two-dimensionally arranged photo detectors 1010. In the example of FIG. 30, a part of the spot 3011 and a part of the spot 3012 are overlapped. Each of monitoring regions 3021 to 3024 is a monitoring region set for each of the spots 3011 to 3014.

Each of output power distributions 3031 to 3034 (#1 to #4) is an output power distribution in the X-direction to be measured based on the spots 3011 to 3014 (#1 to #4). However, in the example of FIG. 30, since a part of the spot 3011 and a part of the spot 3012 are overlapped, a crosstalk portion 3041 in which the output power distribution 3031 and output power distribution 3032 are overlapped is present.

With respect to this, the operation and determination circuit 1840 temporarily calculates the output power distribution 3031 using a gauss approximation from the peak position of the output power distribution 3031. In addition, the operation and determination circuit 1840 temporarily calculates the output power distribution 3032 using a gauss approximation from the peak position of the output power distribution 3032.

The operation and determination circuit 1840 obtains the output power distribution 3031 by subtracting the temporarily calculated output power distribution 3032 from the temporarily calculated output power distribution 3031. In addition, the operation and determination circuit 1840 obtains the output power distribution 3031 by subtracting the temporarily calculated output power distribution 3031 from the temporarily calculated output power distribution 3032.

In this manner, the operation and determination circuit 1840 temporarily calculates the output power through the gauss approximation from the peak position of the power in the spots 3011 and 3012 for the spots 3011 and 3012 including portions overlapped each other. The operation and determination circuit 1840 calculates the output power distributions 3031 and 3032 by subtracting the temporarily calculated power distributions to each other. According to this, even when the crosstalk portion 3041 is generated due to an error during manufacturing of the device or temporal changes during operating, it is possible to estimate the output power distributions 3031 and 3032.

In addition, even when the size or the like of the spots 3011 to 3014 is shifted, the monitoring regions 3021 to 3024 can be dynamically set. Accordingly, it is possible to estimate the output power distribution of each LD of the LD array 1810. In addition, for example, an assembly without depending on the number of arrays or a pitch distance of each LD of the LD array 1810 can be obtained.

Correction of Monitoring Region of LD According to Embodiment

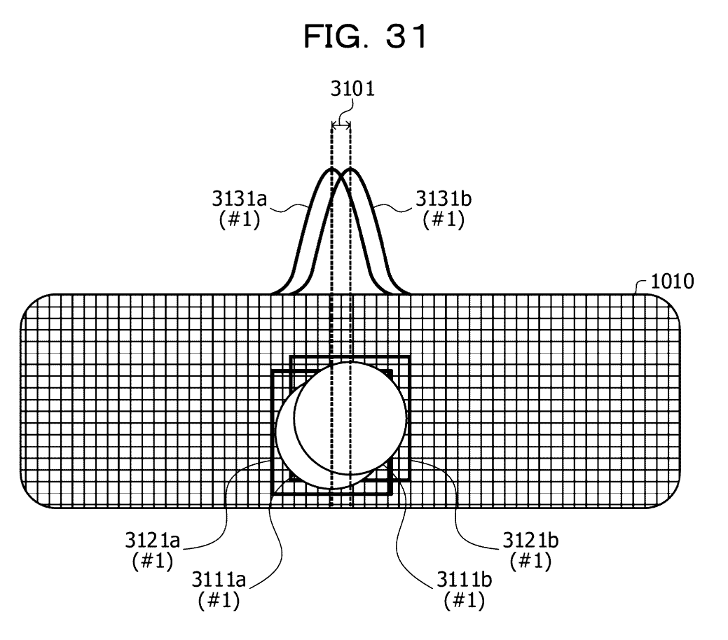

FIG. 31 is a diagram illustrating an example of a correction of a monitoring region of the LD according to the embodiment. A spot 3111a (#1) illustrated in FIG. 31 is a spot of the laser beam radiated from one LD included in the LD array 1810 to the two-dimensionally arranged photo detectors 1010 in a certain time point t1 (for example, at a time when starting of the operation). A monitoring region 3121a (#1) is a monitoring region set for the spot 3111a (#1). An output power distribution 3131a (#1) is an output power distribution of the X-direction to be measured based on the spot 3111a (#1).

A spot 3111b (#1) illustrated in FIG. 31 is a spot of the laser beam radiated from the LD that same as that of the spot 3111a (#1) to the two-dimensionally arranged photo detectors 1010 in a time point t2 after the time point t1 (for example, at a time when during the operation). A monitoring region 3121b (#1) is a monitoring region set for the spot 3111b (#1). An output power distribution 3131b (#1) is an output power distribution of the X-direction to be measured based on the spot 3111b (#1). A positional shifting 3101 indicates a shift between each of peaks of the output power distributions 3131a and 3131b.

As illustrated in FIG. 31, the spot to be radiated to the two-dimensionally arranged photo detectors 1010 may be changed with time changes. The time changes occur due do aging of the LD array 1810 or changes in a positional relationship between the LD array 1810 and the two-dimensionally arranged photo detectors 1010, for example. In addition, it is not limited such the time changes, for example, a position of the spot to be radiated to the two-dimensionally arranged photo detectors 1010 may be greatly shifted due to assembly accuracy at a time when assembling the optical transmission device 1800 or an accuracy of tolerance of the LD array 1810.

With respect to this, the optical transmission device 1800 receives the laser emitted from the LD array 1810 by the two-dimensionally arranged photo detectors 1010 to update the monitoring region based on the peak of the light receiving current of the spot. According to this, even when an optical axis shifting or time changes occur in the LD array 1810 and the two-dimensionally arranged photo detectors 1010, it is possible to continue the determination of the sudden death failure of the LD.

LD Array According to Embodiment

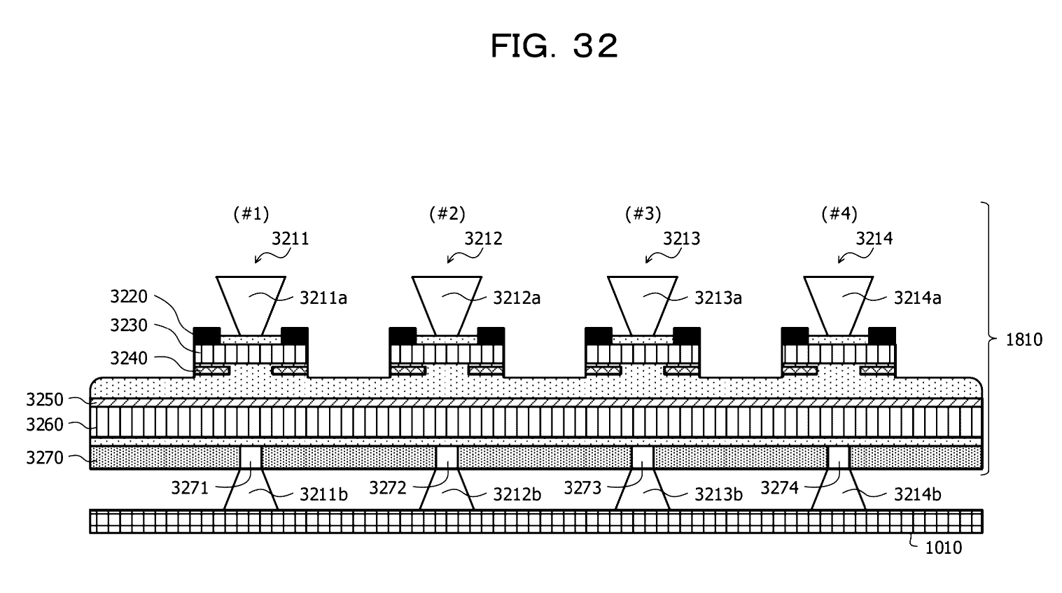

FIG. 32 is a front cross-section view illustrating an example of an LD array according to the embodiment. As illustrated in FIG. 32, as an example, the above-described LD array 1810 can be set as a vertical cavity surface emitting laser (VCSEL) array including limit emitting units 3211 to 3214.

A case where the LD array 1810 includes the four light emitting unit 3211 to 3214 (#1 to #4) will be described. However, the number of light emitting units (LD) of the LD array 1810 is not limited to four, and is, for example, to two or more certain numbers.

In the example illustrated in FIG. 32, the LD array 1810 has a P electrode plate 3220, a distributed bragg reflector (DBR) 3230, an aperture 3240, an active layer 3250, a DBR 3260, and an N electrode plate 3270. In each of the light emitting units 3211 to 3214, for example, the light emitting units emit light by vibrating the light between the DBR 3230 and the DBR 3260 according to the driving signal input to the P electrode plate 3220. The front light beams 3211a to 3214a are front light emitted from each of the light emitting units 3211 to 3214.

In the N electrode plate 3270 that is a client electrode, openings 3271 to 3274 are provided corresponding to the light emitting units 3211 to 3214, respectively. According to this, oscillation light in the light emitting units 3211 to 3214 is emitted from the openings 3271 to 3274, respectively, as back light. Black light beams 3211b to 3214b are back light to be emitted from the light emitting units 3211 to 3214, respectively. The two-dimensionally arranged photo detectors 1010 receive the back light beams 3211b to 3214b omitted from the openings 3271 to 3274.

When inner diameters of the openings 3271 to 3274 are too large, electric light emitting efficiency is deteriorated. In addition, when the inner diameters of the openings 3271 to 3274 are too small, output light is spread by an optical diffraction effect and the crosstalk between adjacent channels becomes greater. For example, the inner diameters of the openings 3271 to 3274 can be set to the diameter about the same as the diameter of the aperture 3240 (for example, 10 μm).

In the LD array 1810 illustrated in FIG. 32, in a semiconductor compound between the DBR 3230 and the N electrode plate 3270 (for example, an InP substrate), it is preferable to use a semi-insulating Fe dope substrate with high optical transmittance, as an example thereof. In addition, in the LD array 1810, it is not limited to the VCSEL, and may be use the LD which vibrates and emits the light in a direction parallel to the substrate surface.

Spot of Back Light of VCSEL Array (at Normal Time) According to Embodiment

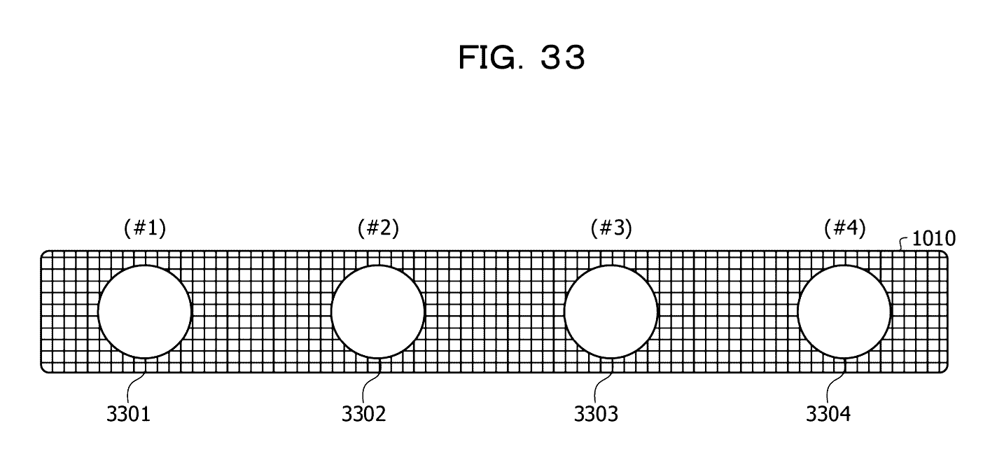

FIG. 33 is a diagram illustrating an example of a spot of a back light of a VCSEL array (at a normal time) according to the embodiment. For example, in the configuration of the LD array 1810 illustrated in FIG. 32, at a normal time when deterioration (sudden death failure sign) in the light emitting units 3211 to 3214 does not occur, the spot to be radiated to the two-dimensionally arranged photo detectors 1010 becomes spots 3301 to 3304 illustrated in FIG. 33. The spots 3301 to 3304 are spots of the back light beams 3211b to 3214b emitted from the openings 3271 to 3274 illustrated in FIG. 32, respectively.

Spot of Back Light of VCSEL Array (at Time when Degradation Occurs) According to Embodiment

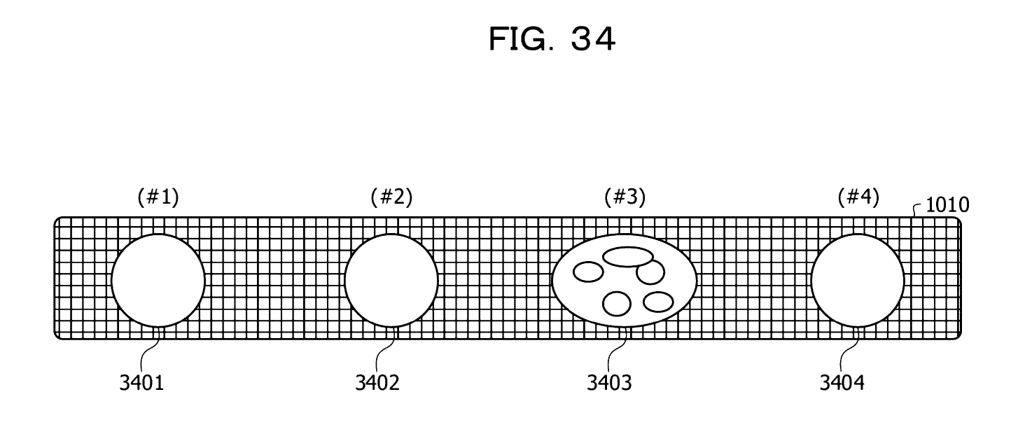

FIG. 34 a diagram illustrating an example of the spot of the back light of the VCSEL array (at a time when degradation occurs) according to the embodiment. For example, in the configuration of the LD array 1810 illustrated in FIG. 32, in a case where the deterioration in the light emitting unit 3213 (#3) occurs among the light emitting units 3211 to 3214, the spot to be radiated to the two-dimensionally arranged photo detectors 1010 becomes spots 3401 to 3404 illustrated in FIG. 34. The spots 3401 to 3404 are spots of the back light beams 3211b to 3214b emitted from the openings 3271 to 3274 illustrated in FIG. 32, respectively. The operation and determination circuit 1840 determines whether there is the sudden death failure sign in the light emitting unit 3213 illustrated in FIG. 32 based on the detection result of the output power distribution of the spot 3403 (#3).

Another Example of LD Array According to Embodiment

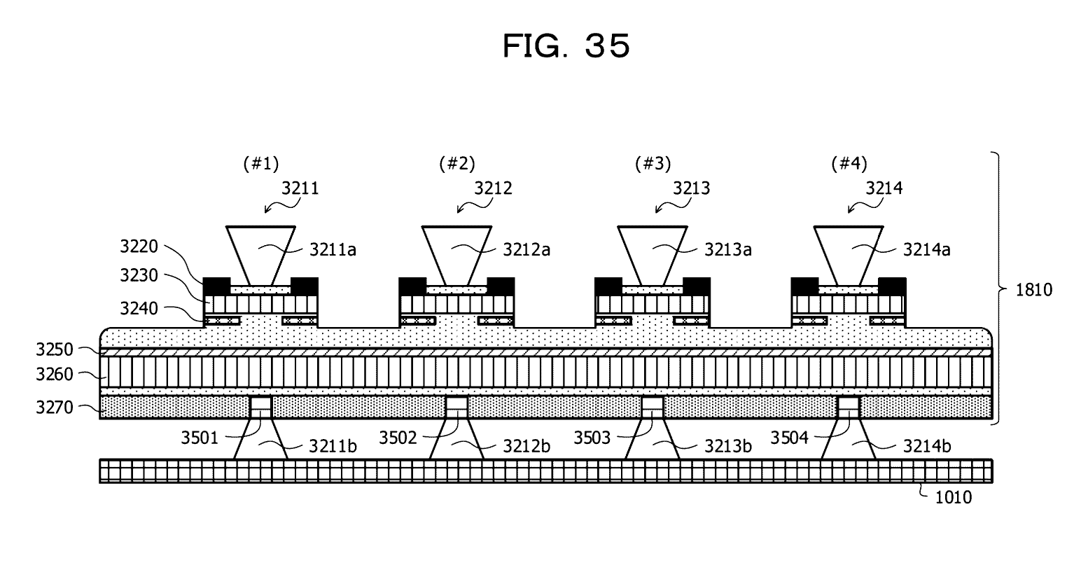

FIG. 35 is a front cross-section diagram illustrating another example of the LD array according to the embodiment. In FIG. 35, same reference numerals are used for denoting the same portion as the portion of FIG. 32 and descriptions thereof will not be described. As illustrated in FIG. 35, in the LD array 1810, transparent conductive films 3501 to 3504 may be provided in the N electrode plate 3270. The transparent conductive films 3501 to 3504 are provided corresponding to the light emitting units 3211 to 3214, respectively, and are formed, for example, in openings 3271 to 3274 illustrated in FIG. 32. The transparent conductive films 3501 to 3504 can be formed by vapor deposition.

According to this, the back light beams 3211b to 3214b of the light emitting units 3211 to 3214 are passed through the two-dimensionally arranged photo detectors 1010 and can suppress the deterioration in electric field characteristics by providing the openings 3271 to 3274 in the N electrode plate 3270. In the transparent conductive films 3501 to 3504, indium tin oxide (ITO) can be used, as an example.

Still Another Example of LD Array According to Embodiment

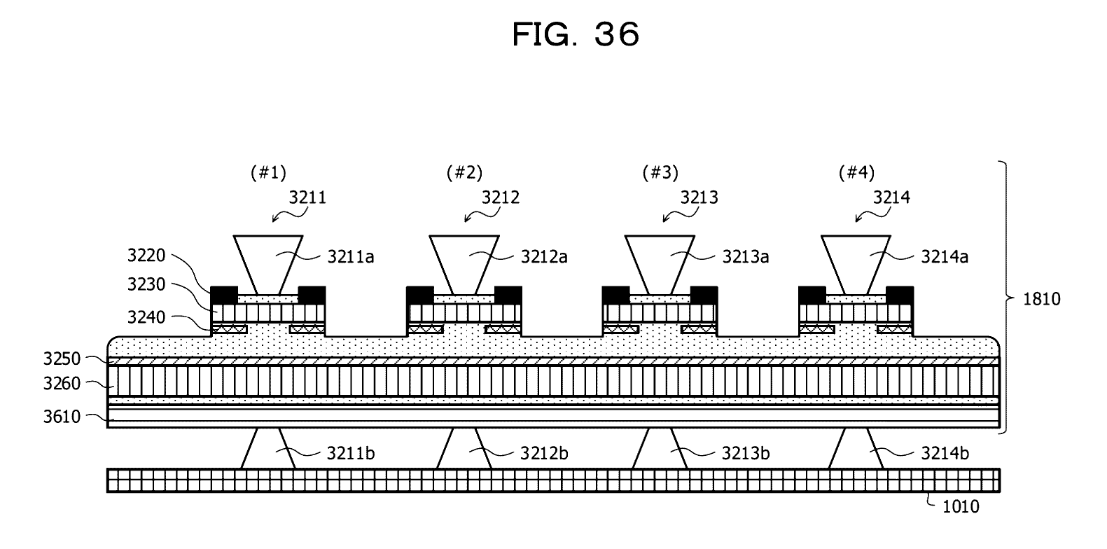

FIG. 36 is a front cross-section diagram illustrating still another example of the LD array according to the embodiment. In FIG. 36, same reference numerals are used for denoting the same portion as the portion of FIG. 32 and descriptions thereof will not be described. As illustrated in FIG. 36, the LD array 1810 may have a configuration that an N electrode plate 3610 which is formed by the transparent conductive film is provided instead of the N electrode plate 3270 illustrated in FIG. 32.

According to this, the back light beams 3211b to 3214b of the light emitting units 3211 to 3214 are passed through the two-dimensionally arranged photo detectors 1010 and can suppress the deterioration in electric field characteristics by providing the openings 3271 to 3274 in the N electrode plate 3270. In the N electrode plate 3610, the ITO can be used, as an example.

Tolerance with Respect to Variation of Spot Radiation According to Embodiment

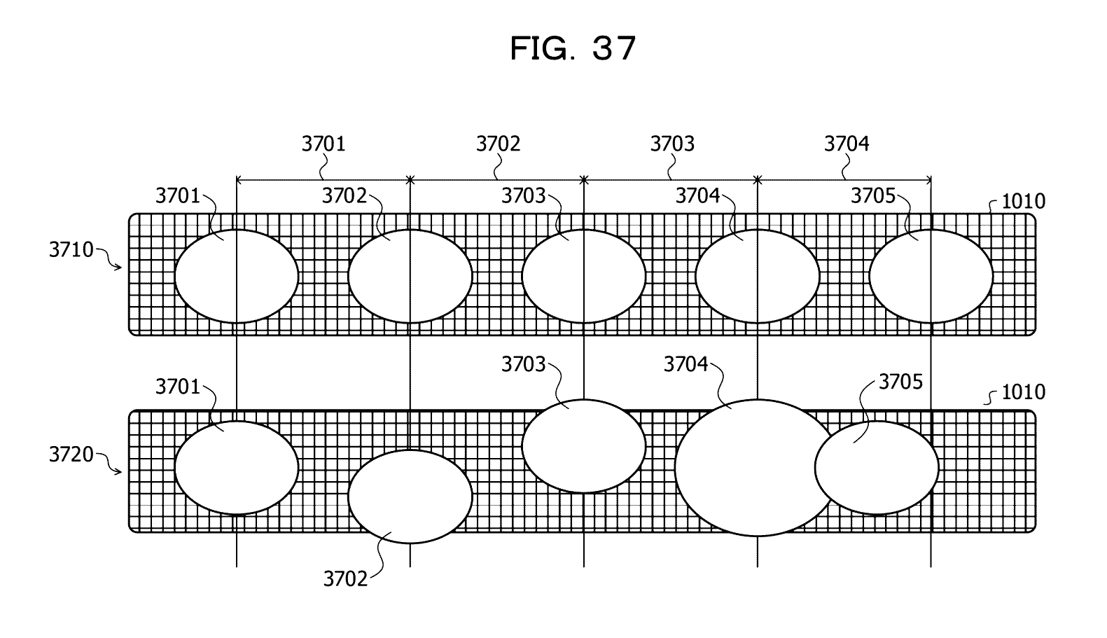

FIG. 37 is a diagram illustrating an example of a tolerance with respect to a variation of a spot radiation according to the embodiment. A spot radiation state 3710 indicates an ideal state of the radiation of each laser beam emitted from the LD array 1810 to the two-dimensionally arranged photo detectors 1010. In the spot radiation state 3710, spots 3701 to 3705 are radiated at equal intervals in a straight line.

A spot radiation state 3720 indicates an actual state of the radiation of each laser beam emitted from the LD array 1810 to the two-dimensionally arranged photo detectors 1010. In the spot radiation state 3720, the positions or sizes of the spots 3701 to 3705 are shifted as compared to the spot radiation state 3710. These shifts occurs due to a dimensional tolerance of the LD array 1810, a power shape or angle of each LD of the LD array 1810, the dimensional tolerance of the two-dimensionally arranged photo detectors 1010, and an error in the alignment adjusting between the LD array 1810 and the two-dimensionally arranged photo detectors 1010.

With respect to this, the optical transmission device 1800 dynamically determines the nominating region of each spot by using the two-dimensionally arranged photo detectors 1010 in which the photo detectors are disposed in the two-dimensionally. Accordingly, it is possible to increase the tolerance with respect to these shifts. Accordingly, since the accuracy desired for above-described each dimension or alignment can be liberalized, it is possible to obtain reduction in a manufacturing cost of the device.

Shift of Positional Relationship Between Two-Dimensionally Arranged Light Receiving Elements and LD Array

In addition, the optical transmission device 1800 may include a control unit for controlling the positional relationship between the two-dimensionally arranged photo detectors 1010 and the LD array 1810 on the XY plane. The control unit can be obtained by actuator or the likes which moves at least one of the two-dimensionally arranged photo detectors 1010 and the LD array 1810.

The control unit minutely changes the positional relationship between the two-dimensionally arranged photo detectors 1010 and the LD array 1810 on the XY plane with time. Accordingly, the radiation positions of the spots 3701 to 3705 with respect to the two-dimensionally arranged photo detectors 1010 are minutely changed. According to this, the detection positions (monitoring regions) of the spots 3701 to 3705 are changed with time, and the spots 3701 to 3705 are radiated in only a certain photo detector, in the two-dimensionally arranged photo detectors 1010. Accordingly, it is possible to suppress the deterioration in the photo detector.

Characteristic Change in LD According to Embodiment

FIG. 38 is a diagram illustrating an example of a characteristic change in the LD according to the embodiment. In FIG. 38, the horizontal axis indicates a time. A life specification 3810 is a timing of a life time on a specification in the LD 110. In the example illustrated in FIG. 38, the life specification 3810 is about 10 years.

An efficiency change 3801 indicates a temporal change of the efficiency (mW/mA) of lighting conversion≅optical output power in the LD 110 (article with a good condition) in which the sudden death failure does not occur. In the efficiency change 3801, the efficiency of the lighting conversion is slowly deteriorated with time.

An efficiency change 3802 indicates a temporal change of the efficiency (mW/mA) of lighting conversion≅optical output power in the LD 110 (article with sudden death failure) in which the sudden death failure occurs. In the efficiency change 3802, the efficiency of the lighting conversion is slowly deteriorated with time and is rapidly deteriorated to 0 (sudden death failure) at a certain time point (for example, a time point earlier than the life specification 3810).

A fitting coefficient change 3803 indicates a temporal change of the above-described fitting coefficient (σx or σy) in the LD 110 (article with sudden death failure). In the fitting coefficient change 3803, the fitting coefficient becomes gradually greater from a time point earlier that a time point when the sudden death failure occurs. In the LD 110 in which the sudden death failure occurs, a confinement of light becomes weakened and the optical power distribution becomes wider. In addition, the fitting coefficient is rapidly deteriorated when the sudden death failure occurs.

A fitting coefficient change 3804 indicates a temporal change of the correlation coefficient ρ in the LD 110 (article with sudden death failure) in which the sudden death failure sign occurs. In the fitting coefficient change 3804, the correlation coefficient ρ is about 1.0 in an initial state, and becomes gradually reduced from a time point earlier than the time position when the sudden death failure occurs. The optical power distribution of the LD 110 in which the sudden death failure occurs is slowly deformed from the ideal gaussian shape when earlier than the time point when the sudden death failure occurs. In addition, the correlation coefficient ρ is rapidly deteriorated.

A fitting coefficient change 3805 indicates a temporal change of the number of peaks of the above-described two-dimensionally optical power distribution in the LD 110 (article with sudden death failure) in which the sudden death failure occurs. In the fitting coefficient change 3805, the number of the peaks is 1 in an initial state, and becomes gradually increased from a time point earlier than the time position when the sudden death failure occurs. The optical power distribution of the LD 110 in which the sudden death failure occurs is deformed and a new peak is generated. In addition, the number of the peaks is rapidly reduced when the sudden death failure occurs.

An oscillation wavelength change 3806 indicates a temporal change in oscillation wavelengths in the LD 110 (article with sudden death failure) in which the sudden death failure occurs as a reference. In the oscillation wavelength change 3806, the oscillation wavelength is shortened at a time point slightly earlier than the time point when the sudden death failure occurs.

As illustrated in FIG. 38, feature values of the two-dimensionally optical power distribution such as the above-described fitting coefficient (σx, σy), the correlation coefficient ρ, and the number of peaks are changed from the initial value earlier than the time point when the LD 110 is in the sudden death failure. Accordingly, the sudden death failure sign of the LD 110 is determined based on these features points. Therefore, the sudden death failure of the LD 110 can predict early.

For example, since the changes in the feature values occur earlier than the changes in the oscillation wavelengths discussed in the oscillation wavelength change 3806, by monitoring the changes in the feature values, the sudden death failure sign of the LD 110 can be predicted earlier than when monitoring the changes in the oscillation wavelengths. Since the sudden death failure sign of the LD 110 can be predicted even without the configuration for monitoring the changes in the oscillation wavelengths (for example, a wavelength filter and a plurality of PDs), it is possible to obtain reduction in a manufacturing cost of the device.

In this manner, according to the laser device 100 according to the embodiment, power in each position of the spot of the emission light of the LD 110 can be detected. According to the laser device 100, the power distribution of the spot of the LD 110 and the total power of the emission light of the LD 110 can be calculated based on the detected power in each position. Accordingly, the sudden death failure sign of the LD 110 can be determined based on the calculation result. According to this, the sudden death failure sign of the LD 110 can be predicted early and with high accuracy.

In addition, in FIGS. 7 to 38, the configuration for detecting the power in each position of the two-dimensional output power distribution in the spot of the emission light of the LD 110 is described. However, the configuration is not limited thereto. For example, a configuration for detecting a one-dimensional output power distribution (for example, the output power distributions 800 and 900 illustrated in FIGS. 8 and 9, the output power distribution 1500 illustrated in FIG. 15, and the output power distribution 1600 illustrated in FIG. 16) in the spot of the emission light of the LD 110 may be used. In this case, the sudden death failure sign of the LD 110 can be predicted early and with high accuracy. By using the configuration for detecting the two-dimensional output power distribution in the spot, the sudden death failure sign of the LD 110 can be predicted early and with high accuracy regardless of a deforming direction from the gaussian distribution of the two-dimensional output power distribution of the spot.

In FIGS. 7 to 38, the determination of the sudden death failure sign of the LD 110 in the laser device 100 is described mainly. However, in the same manner as the LD 110 of the optical amplifier 130 or the SOA 151 of the optical amplifier 150, the sudden death failure sign of the LD 110 can be predicted early and with high accuracy.

As described above, according to the laser device, the optical amplifier, the optical transmission device, and the determination method, the sudden death failure sign of the semiconductor optical device can be predicted early and with high accuracy.

For example, main factors affecting reliability of the optical communicating system is a failure and life time of optical components. Among the various types of optical components, the failure and life time of the LD that is a main component for performing an optical communication is a significant factor. In the LD, there is known a failure mode of the sudden death failure sign that the optical output power suddenly is not appeared, in addition to the failure mode that the optical output power is deteriorated little by little over time (wear-out failure). With respect to this, according to the above-described embodiment, for example, it is possible to provide a service with high reliability while maintaining the low cost in the optical communicating system by autonomously recognizing and focusing on the sudden death failure sign of the LD during in-service. The above-described embodiment is possible to apply, for example, to a transceiver, an excitation light source for an optical fiber amplifier, and a semiconductor optical amplifier.

In addition, for example, the sudden death failure of the LD can be detected by monitoring the back light of the front light of the LD. However, it is difficult to detect the sudden death failure sign of the LD. Specifically, in a case where the LD is combined with a multimode fiber, even when the optical output power distribution of the LD is changed from the gaussian, since the core diameter of the multimode fiber is larger, the changes in the optical output power does not occurs or changed very little. Therefore, in the related art, it is difficult to detect the sudden death failure sign of the LD.

With respect to this, according to the above-described embodiment, by detecting the power in the each position of the spot of the emission light of the LD and determining using the power distribution of the spot of the LD, it is possible to detect the sudden death failure of the LD early. Furthermore, according to the embodiment, by additionally determining the total power of the spot of the LD, it is possible to detect the sudden death failure of the LD with high accuracy.

In addition, in an optical module using the conventional VCSEL array, for example, by setting a margin of a sufficient optical level in advance without performing the optical power monitoring, the deterioration of the optical output power to be expected is absorbed. For example, the configuration does not fully demonstrate the performance of the optical device. For example, the configuration equipped with an optical power monitor of the optical module at the expense of a transmission distance or a transmission speed is not implemented.

In addition, since a detecting unit for the sudden death failure sign of the VCSEL array is not provided, for example, by providing the lengthy configuration at the system side, it is obtained to enhance the reliability of the optical module in the entire system. For example, by constructing a plurality of optical network between the same links, disposing each working link and standby link, and providing a configuration such as transmitting and receiving data to double all of the time, the lengthy of the network can be obtained and it corresponds to the sudden death failure of the VCSEL array.

Alternatively, as another method, by providing the standby VCSEL in the VCSEL array, an operation is performed by switching the signal to be transmitted to the standby VCSEL using the electrical switch, in a case where there is no error (signal interrupted) due to the sudden death failure. In all of the methods, it leads to increase in the size of the system, in power consumption, and in the cost.

With respect to this, according to the embodiment, the sudden death failure sign of the VCSEL array can be predicted, or exchange of the VCSEL array can be performed by planned switching to the lengthy configuration at the time point when the sudden death failure sign is detected. Accordingly, the configuration, that a lengthy configuration of the optical link or the standby VCSEL is prepared, is not to be used, and it is possible to simplify the configuration of the system while maintaining the high reliability.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiment of the present invention has been described in detail, it should be understood that the various changes, substitutions, and alterations could be made hereto without departing from the spirit and scope of the invention.

What is claimed is:

1. A laser device comprising:
a semiconductor laser;
a detection circuit which detects optical power in each position of a spot of emission light which is emitted from the semiconductor laser; and
a determination circuit which calculates a power distribution of the spot of the emission light and total power of the spot based on the optical power detected by the detection circuit to determine a sudden death failure sign of the semiconductor laser based on the calculated power distribution and the total power.

2. The laser device according to claim 1,
wherein the determination circuit determines that
there is the sudden death failure sign in the semiconductor laser, in a case where the power distribution satisfies a first condition and the total power satisfies a second condition, and
there is no sudden death failure sign in the semiconductor laser, in a case where the power distribution does not satisfy the first condition or the total power does not satisfy the second condition.

3. The laser device according to claim 2,
wherein the determination circuit determines that
there is the sudden death failure sign in the semiconductor laser, in a case where a magnitude of a difference between a feature value of a shape of the power distribution and a first reference value is equal to or greater than a first threshold value and a magnitude of a difference between the total power and a second reference value is less than a second threshold value, and
there is no sudden death failure sign in the semiconductor laser, in a case where the magnitude of the difference between the feature value and the first reference value is less than the first threshold value and the magnitude of the difference between the total power and the second reference value is equal to or greater than the second threshold value.

4. The laser device according to claim 3,
wherein the first reference value is an initial value of the feature value, and
the second reference value is an initial value of the total power.

5. The laser device according to claim 1,
wherein the power distribution is a two-dimensional power distribution of the spot.

6. The laser device according to claim 1,
wherein the detection circuit detects optical power in each position having a pitch narrower than a width of the spot, that is, each position of a region wider than the spot.

7. The laser device according to claim 1, further comprising:
a plurality of semiconductor lasers,
wherein the detection circuit detects the optical power in each position having the pitch narrower than the width of the spot, that is, each position of a region including the spot of each semiconductor laser,
the determination circuit calculates the power distribution and the total power for each semiconductor laser based on the optical power in each position of the region detected by the detection circuit to determine the sudden death failure sign of each semiconductor laser based on the calculated power distribution and the total power, and
the determination circuit temporarily operates each power distribution through a gauss approximation from a peak position of the optical power in each spot with respect to each spot including a portion where the spots are overlapped with each other among the spots of each of the semiconductor laser, and calculates each power distribution of each of the spots by subtracting the temporarily operated power distributions each other.

8. The laser device according to claim 1,
wherein the semiconductor laser is a vertical cavity surface emitting laser,
a ground electrode of the vertical cavity surface emitting laser has an opening for emitting back light which emitted from the vertical cavity surface emitting laser, and
the detection circuit detects optical power in each position of the spot of the back light emitted from the opening.

9. The laser device according to claim 8,
a transparent conductive film through which the back light is transmitted is formed on the opening.

10. The laser device according to claim 1,
wherein the semiconductor laser is a vertical cavity surface emitting laser,
a ground electrode of the vertical cavity surface emitting laser is formed by a transparent conductive film through which the back light of the vertical cavity surface emitting laser is transmitted, and
the detection circuit detects optical power in each position of the spot of the back light emitted from the ground electrode.

11. The laser device according to claim 1,
wherein the detection circuit is a plurality of photo detectors arranged two dimensionally.

12. The laser device according to claim 1,
wherein the determination circuit determines the sudden death failure sign of the semiconductor laser based on at least one of a spread of the power distribution of the spot of the emission light and a change in the number of peaks of the power distribution of the spot of the emission light.

13. An optical amplifier comprising:
a semiconductor laser;
an optical amplification medium which allows incident light and emission light emitted from the semiconductor laser to be passed to amplify and emit the incident light;
a detection circuit which detects optical power in each position of a spot of the emission light; and
a determination circuit which calculates a power distribution of the spot of the emission light and total power of the spot based on the optical power detected by the detection circuit to determine a sudden death failure sign of the semiconductor laser based on the calculated power distribution and the total power.

14. An optical amplifier comprising:
a semiconductor optical amplifier;
a detection circuit which detects optical power in each position of a spot of emission light which is emitted from the semiconductor optical amplifier; and
a determination circuit which calculates a power distribution of the spot of the emission light and total power of the spot based on the optical power detected by the detection circuit to determine a sudden death failure sign of the semiconductor optical amplifier based on the calculated power distribution and the total power.

15. The optical amplifier according to claim 14,
wherein the emission light is an amplified spontaneous emission light emitted from the semiconductor optical amplifier.

16. An optical transmission device comprising:
a semiconductor laser which emits an optical signal based on an input data signal;
a detection circuit which detects optical power in each position of a spot of emission light which is emitted from the semiconductor laser; and
a determination circuit which calculates a power distribution of the spot of the emission light and total power of the spot based on the optical power detected by the detection circuit to determine a sudden death failure sign of the semiconductor laser based on the calculated power distribution and the total power.

17. A determination method for determining a sudden death failure sign of a semiconductor laser or a semiconductor optical amplifier, the method comprising:
detecting optical power in each position of a spot of emission light which is emitted from the semiconductor laser or the semiconductor optical amplifier;
calculating a power distribution of the spot of the emission light and total power of the spot based on the detected optical power; and
determining the sudden death failure sign of the semiconductor laser or the semiconductor optical amplifier based on the calculated power distribution and the total power.
